(19) United States
(12) Patent Application Publication
(10) Pub. No.: US 2013/0093092 A1
(43) Pub. Date: Apr. 18, 2013

(54) ELECTRONIC DEVICE AND METHOD FOR PRODUCING SAME

(71) Applicants: Tsuyoshi Kanki, Atsugi (JP); Hideki Kitada, Atsugi (JP)

(72) Inventors: Tsuyoshi Kanki, Atsugi (JP); Hideki Kitada, Atsugi (JP)

(73) Assignee: FUJITSU LIMITED, Kawasaki-shi (JP)

(21) Appl. No.: 13/613,167

(22) Filed: Sep. 13, 2012

(30) Foreign Application Priority Data
Oct. 17, 2011 (JP) 2011-228333

(51) Int. Cl. H01L 23/52; H01L 21/768

(52) U.S. Cl. 257/758; 438/637; 257/E23.141; 257/E21.577

(57) ABSTRACT

An electronic device includes: a first insulating film; an interconnection trench on a surface of the first insulating film; an interconnection pattern composed of Cu, the interconnection trench being filled with the interconnection pattern; a metal film on a surface of the interconnection pattern, the metal film having a higher elastic modulus than Cu; a second insulating film on the first insulating film; and a via plug composed of Cu and arranged in the second insulating film, the via plug being in contact with the metal film.

### CROSS-REFERENCE TO RELATED APPLICATION(S)

This application is based upon and claims the benefit of priority of the prior Japanese Patent Application No. 2011-228333, filed on Oct. 17, 2011, the entire contents of which are incorporated herein by reference.

### FIELD

The embodiments discussed herein are generally related to electronic devices, and particularly to an interconnection structure for use in an electronic device and a method for producing the electronic device.

### BACKGROUND

Multilayer interconnection structures have been used to form interconnections in various circuit boards ranging from fine devices, such as large-scale integrated (LSI) circuits, to printed circuit boards.

Nowadays, trends toward miniaturization, higher performance, lower cost, and so forth of electronic devices lead to the formation of very fine, complex interconnection structures of semiconductor integrated circuit devices. As higher performance of semiconductor chips, trends toward an increase in the number of terminals and a reduction in size lead to the formation of very fine interconnection structures in circuit boards used for various packages. In the field of circuit boards, what is called a semi-additive process that includes forming a plating seed layer on an insulating substrate, such as a resin build-up substrate, forming a resist pattern thereon, and then forming a desired interconnection pattern by electroplating; and a subtractive process that includes etching copper foil on an insulating substrate to form an interconnection pattern have been widely employed.

However, an interconnection pattern formed by the semi-additive process or the subtractive process has the following problem: In particular, in the case of a fine interconnection pattern, the interconnection pattern detaches or falls easily because the interconnection pattern is a self-supporting pattern formed on an underlying circuit board.

Meanwhile, in the field of LSIs, a damascene process has been employed to form a multilayer interconnection structure containing low-resistance Cu. In the damascene process, an interconnection structure is formed by forming an interconnection trench and a via hole corresponding to a desired interconnection pattern and a via plug in an insulating film, filling them with a Cu layer, and removing an excess portion of the Cu layer by a chemical-mechanical polishing (CMP) method. An interconnection pattern formed by the damascene process is mechanically stable and has the advantage in that problems of detachment and falling down are less likely to occur because the interconnection pattern is supported by the insulating film from the side. The interconnection structure formed by the damascene process also has the following advantages: The interconnection structure has a flat shape because the interconnection pattern is formed by chemical-mechanical polishing for each insulating film. Thus, a multilayer interconnection structure is easily formed by stacking another interconnection structure on the interconnection structure.
[Patent Document] Japanese Laid-open Patent Publication No. 2001-60589
[Patent Document] Japanese Laid-open Patent Publication No. 2001-284351
[Patent Document] Japanese Laid-open Patent Publication No. 2006-41036

FIGS. 1A to 1F are cross-sectional views illustrating a method for producing an interconnection structure by a typical damascene process.

Referring FIG. 1A, an insulating film 12 composed of an inorganic or organic material is formed on an insulating film 10 including interconnection patterns 10A to 10D or on a substrate with a diffusion barrier film 11 composed of, for example, SiC or SiN. Via holes 12B and 12D that expose the underlying interconnection patterns 10B and 10D and interconnection trenches 12A, 12C, and 12E are formed in the insulating film 12 by dry etching or photolithography. In the example illustrated in the FIG. 1A, the via hole 12D overlaps the interconnection trench 12E.

For example, in the case where the insulating film 12 is a SiO₂ film, a SiC film, or another low-k organic or inorganic film, the via holes 12B and 12D and the interconnection trenches 12C and 12E may be formed by dry etching. In the case where the insulating film 12 is a photosensitive permanent resist, the via holes 12B and 12D and the interconnection trenches 12C and 12E may be formed by photolithography.

In FIG. 1A, the interconnection patterns 10A to 10D are buried in the insulating film 10 via barrier metal films 10a to 10d, respectively.

As illustrated in FIG. 1B, a barrier metal film 13, which is typically a high-melting-point metal film composed of, e.g., Ti, Ta, or w, or a conductive film of a nitride thereof, is formed on the structure depicted in FIG. 1A by, for example, a sputtering method or a chemical vapor deposition (CVD) method so as to cover surfaces of the via holes 12B and 12D and the interconnection trenches 12C and 12E.

As illustrated in FIG. 1C, a conductive Cu seed layer 14 is formed by, for example, a sputtering method, a CVD method, or an electroless plating method on the structure illustrated in FIG. 1B. The structure illustrated in FIG. 1C is immersed in an electroplating bath (not illustrated). The Cu seed layer 14 is energized, so that the via holes 12B and 12D and the interconnection trenches 12C and 12E on the insulating film 12 are filled, thereby forming a Cu layer 15 by electroplating as illustrated in FIG. 1D.

This electroplating process is typically performed in such a manner that the via holes 12B and 12D and the interconnection trenches 12C and 12E are filled upward from the bottom (bottom up) while the formation of voids and seams in the Cu layer 15 is inhibited by the addition of a brightener (also referred to as an accelerator), a suppressant (also referred to as a polymer or suppressor), and a smoothing agent (also referred to as a leveler) to a virgin make-up solution (VMS) containing Cu ions, H₂SO₄, Cl ions, and so forth.

As illustrated in FIG. 1E, the resulting Cu layer 15 is subjected to chemical-mechanical polishing until the upper surface of the insulating film 12 is exposed. Thereby, Cu via plugs 15PB and 15PD and Cu interconnection patterns 15WA, 15WC, and 15WE are formed of the Cu layer 15 in the via holes 12B and 12D and the interconnection trenches 12A, 12C, and 12E.

As illustrated in FIG. 1F, a diffusion barrier film 16 composed of SiN or SiC is formed as a cap film on the insulating film 12, the diffusion barrier film 16 covering the Cu via plugs 15PB and 15PD and the Cu interconnection patterns 15WA, 15WC, and 15WE.

Such multilayer interconnection structures are widely used for various electronic devices including semiconductor devices. In the case of high-heat-generating recent electronic devices, such multilayer interconnection structures have often been subjected to severe stress by the repetition of thermal expansion and contraction due to heat generated during operation. Thus, a multilayer interconnection structure that may stably maintain contact even if thermal cycle is applied thereto is desired.

In the case where the damascene process is employed as described above, it is possible to form a flat, mechanically stable interconnection structure with the insulating film 12, the Cu via plugs 15PB and 15PD, and the Cu interconnection patterns 15WA, 15WC, and 15WE. As described below, some interconnection patterns formed in the insulating film 12 cause variations or nonuniformity in the thickness of the Cu layer 15 on the insulating film 12 at the stage illustrated in FIG. 1D, depending on the interconnection patterns. Disadvantageously, the variations are not resolved by subsequent chemical-mechanical polishing, in some cases.

FIG. 2 illustrates an example in which variations or nonuniformity in the thickness of the Cu layer 15 occurs, depending on the interconnection patterns.

Referring to FIG. 2, a wide, shallow interconnection trench 12A having a width of 10.0 μm and a depth of 1.5 μm is arranged in a region B of the insulating film 12. In a region B, interconnection trenches 12B each having a width of 1.0 μm and a depth of 1.5 μm are arranged at a pitch of 1.0 μm to form a line-and-space pattern. In the case where this structure is filled with the Cu layer 15 by the electroplating method illustrated in FIG. 1D, the Cu layer 15 bulges in the region A as illustrated in FIG. 2. That is, the Cu layer 15 is in what is called an overplating state in the region B. In a region A, the Cu layer 15 is recessed. That is, the Cu layer 15 is in what is called an underplating state in the region A. The underplating occurs typically when the width of an interconnection trench is 5 or more times the depth of the interconnection trench (in other words, when the aspect ratio or the depth-to-width ratio is 1/5 or less).

In the case where the Cu layer 15 having portions where the overplating and underplating occur is polished by chemical-mechanical polishing, the portion where the overplating occurs and the portion where the underplating occurs are both polished. As illustrated in FIG. 3, the region B is thus planarized to have a state in which the interconnection trenches 12B are filled with Cu layers 15B to a surface of the insulating film 12 and surfaces of the Cu layers 15B are flush with the surface of the insulating film 12. In the region A, a Cu layer 15A formed in the interconnection trench 12A is recessed.

That is, what is called dishing occurs. In FIG. 3, the left drawing of illustrates a state before the chemical-mechanical polishing depicted in FIG. 2, and the right drawing illustrates a state after the chemical-mechanical polishing. In the case where an upper interconnection structure is formed on an underlying interconnection structure where dishing occurs, a via plug in the upper interconnection structure may fail to reach a desired interconnection pattern in the underlying interconnection structure.

The polish rate at the portion of the Cu layer where the underplating occurs is lower than that at the portion of the Cu layer where the overplating occurs. Thus, measures in which the Cu layer 15 with a large thickness is formed and chemical-mechanical polishing is performed to provide a flat surface extending from the overplating portion to the underplating portion have been taken in the past. In the case of the measures taken in the past, however, for example, the electroplating illustrated in FIG. 1D and the chemical-mechanical polishing illustrated in FIG. 1E are performed for a long time, thus wasting resources, such as slurry and Cu, to cause an increase in the formation cost of the interconnection structure.

### SUMMARY

According to an aspect of the embodiments, an electronic device includes: a first insulating film; an interconnection trench on a surface of the first insulating film; an interconnection pattern composed of Cu, the interconnection trench being filled with the interconnection pattern; a metal film on a surface of the interconnection pattern, the metal film having a higher elastic modulus than Cu; a second insulating film on the first insulating film; and a via plug composed of Cu and arranged in the second insulating film, the via plug being in contact with the metal film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a cross-sectional view (1) illustrating a method for forming an interconnection structure by a typical damascene process;

FIG. 1B is a cross-sectional view (2) illustrating the method for forming an interconnection structure by the typical damascene process;

FIG. 1C is a cross-sectional view (3) illustrating the method for forming an interconnection structure by the typical damascene process;

FIG. 1D is a cross-sectional view (4) illustrating the method for forming an interconnection structure by the typical damascene process;

FIG. 1E is a cross-sectional view (5) illustrating the method for forming an interconnection structure by the typical damascene process;

FIG. 1F is a cross-sectional view (6) illustrating the method for forming an interconnection structure by the typical damascene process;

FIG. 2 is a cross-sectional view illustrating a problem;

FIG. 3 is another cross-sectional view illustrating the problem;

FIG. 4A is a cross-sectional view (1) illustrating a method for forming an interconnection structure according to a first embodiment;

FIG. 4B is a cross-sectional view (2) illustrating the method for forming an interconnection structure according to the first embodiment;

FIG. 4C is a cross-sectional view (3) illustrating the method for forming an interconnection structure according to the first embodiment;

FIG. 4D is a cross-sectional view (4) illustrating the method for forming an interconnection structure according to the first embodiment;

FIG. 4E is a cross-sectional view (5) illustrating the method for forming an interconnection structure according to the first embodiment;

FIG. 4F is a cross-sectional view (6) illustrating the method for forming an interconnection structure according to the first embodiment;

FIG. 4G is a cross-sectional view (7) illustrating the method for forming an interconnection structure according to the first embodiment;

FIG. 4H is a cross-sectional view (8) illustrating the method for forming an interconnection structure according to the first embodiment;

FIG. 4I is a cross-sectional view (9) illustrating the method for forming an interconnection structure according to the first embodiment;

FIG. 4J is a cross-sectional view (10) illustrating the method for forming an interconnection structure according to the first embodiment;

FIG. 4K is a cross-sectional view (11) illustrating the method for forming an interconnection structure according to the first embodiment;

FIG. 4L is a cross-sectional view (12) illustrating the method for forming an interconnection structure according to the first embodiment;

FIG. 4M is a cross-sectional view (13) illustrating the method for forming an interconnection structure according to the first embodiment;

FIG. 4N is a cross-sectional view (14) illustrating the method for forming an interconnection structure according to the first embodiment;

FIG. 5A is a cross-sectional view (1) illustrating a method for forming an interconnection structure according to a second embodiment;

FIG. 5B is a cross-sectional view (2) illustrating the method for forming an interconnection structure according to the second embodiment;

FIG. 5C is a cross-sectional view (3) illustrating the method for forming an interconnection structure according to the second embodiment;

FIG. 5D is a cross-sectional view (4) illustrating the method for forming an interconnection structure according to the second embodiment;

FIG. 5E is a cross-sectional view (5) illustrating the method for forming an interconnection structure according to the second embodiment;

FIG. 5F is a cross-sectional view (6) illustrating the method for forming an interconnection structure according to the second embodiment;

FIG. 5G is a cross-sectional view (7) illustrating the method for forming an interconnection structure according to the second embodiment;

FIG. 6A is a cross-sectional view illustrating definitions of parameters in examples;

FIG. 6B is another cross-sectional view illustrating definitions of parameters in the examples;

FIG. 7 is a graph illustrating advantages of the embodiments;

FIG. 8 is a cross-sectional view illustrating a multilayer circuit board according to a third embodiment;

FIGS. 9A and 9B are cross-sectional views illustrating the suppression of stress migration in the third embodiment;

FIGS. 10A and 10B are cross-sectional views illustrating problems in the case where stress migration is not suppressed;

FIG. 11 illustrates the simulation results of stress distributions according to the third embodiment;

FIG. 12 is a cross-sectional view illustrating a model multilayer interconnection structure used in the simulation in FIG. 11;

FIG. 13A is a cross-sectional view (1) illustrating a process for producing the model structure illustrated in FIG. 12;

FIG. 13B is a cross-sectional view (2) illustrating the process for producing the model structure illustrated in FIG. 12;

FIG. 13C is a cross-sectional view (3) illustrating the process for producing the model structure illustrated in FIG. 12;

FIG. 13D is a cross-sectional view (4) illustrating the process for producing the model structure illustrated in FIG. 12;

FIG. 13E is a cross-sectional view (5) illustrating the process for producing the model structure illustrated in FIG. 12;

FIG. 13F is a cross-sectional view (6) illustrating the process for producing the model structure illustrated in FIG. 12;

FIG. 13G is a cross-sectional view (7) illustrating the process for producing the model structure illustrated in FIG. 12;

FIG. 13H is a cross-sectional view (8) illustrating the process for producing the model structure illustrated in FIG. 12;

FIG. 13I is a cross-sectional view (9) illustrating the process for producing the model structure illustrated in FIG. 12;

FIG. 14 is a cross-sectional view illustrating a multilayer interconnection structure according to a modification of the third embodiment;

FIG. 15A is a cross-sectional view (1) illustrating a process for producing the structure illustrated in FIG. 14;

FIG. 15B is a cross-sectional view (2) illustrating the process for producing the structure illustrated in FIG. 14;

FIG. 15C is a cross-sectional view (3) illustrating the process for producing the structure illustrated in FIG. 14;

FIG. 15D is a cross-sectional view (4) illustrating the process for producing the structure illustrated in FIG. 14;

FIG. 15E is a cross-sectional view (5) illustrating the process for producing the structure illustrated in FIG. 14;

FIG. 15F is a cross-sectional view (6) illustrating the process for producing the structure illustrated in FIG. 14;

FIG. 15G is a cross-sectional view (7) illustrating the process for producing the structure illustrated in FIG. 14;

FIG. 15H is a cross-sectional view (8) illustrating the process for producing the structure illustrated in FIG. 14;

FIG. 15I is a cross-sectional view (9) illustrating the process for producing the structure illustrated in FIG. 14;

FIG. 15J is a cross-sectional view (10) illustrating the process for producing the structure illustrated in FIG. 14;

FIG. 16 is a cross-sectional view illustrating a semiconductor integrated circuit device according to the fourth embodiment;

FIG. 17 is a table illustrating experimental conditions of examples; and

FIG. 18 is a table illustrating evaluations of experiments.

### DESCRIPTION OF EMBODIMENTS

### First Embodiment

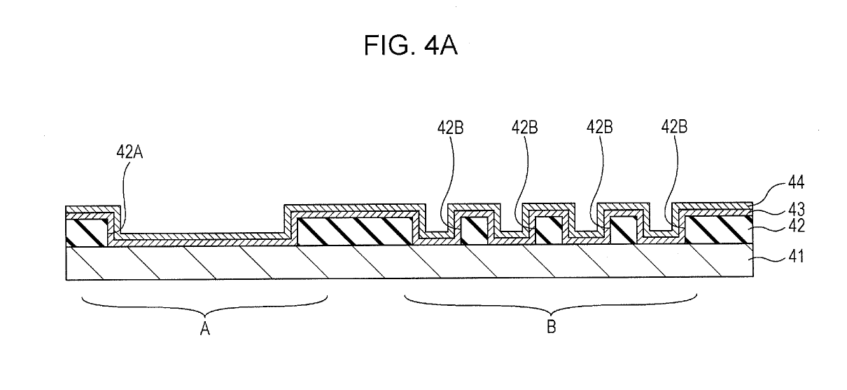

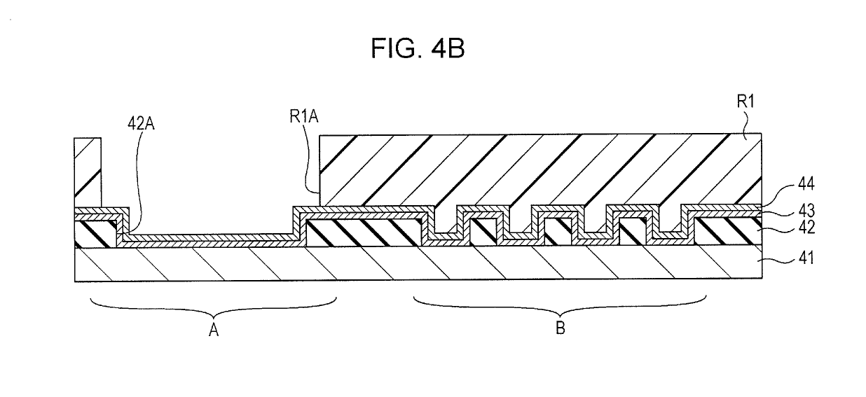

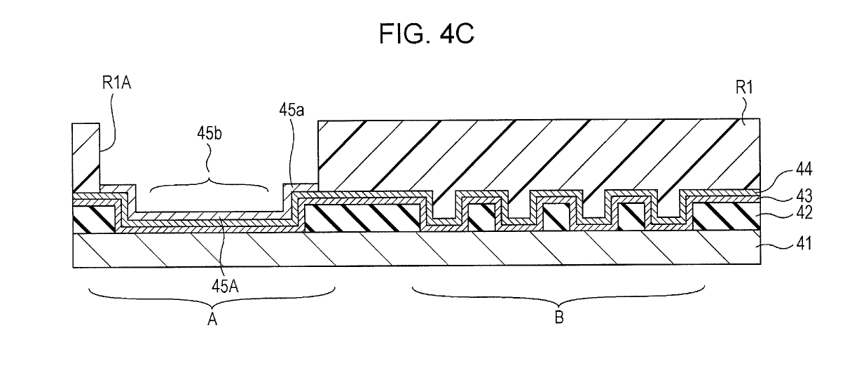

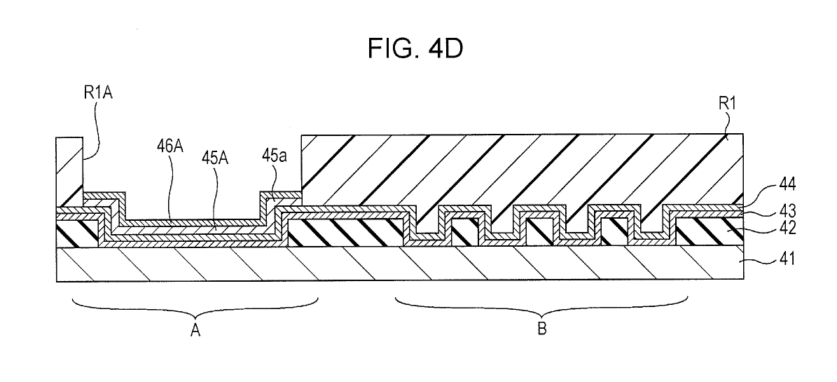

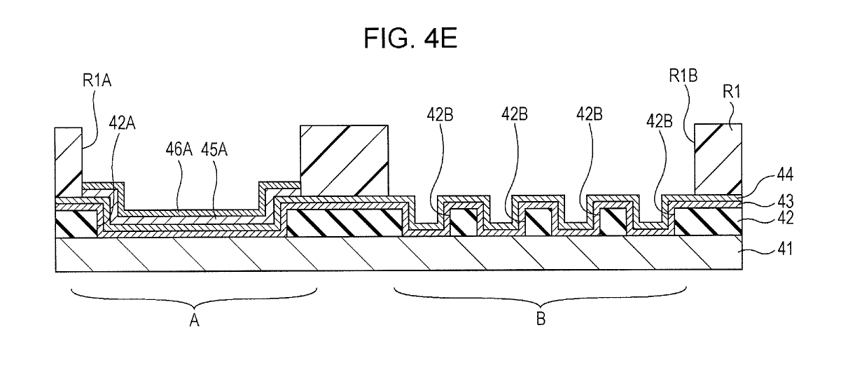

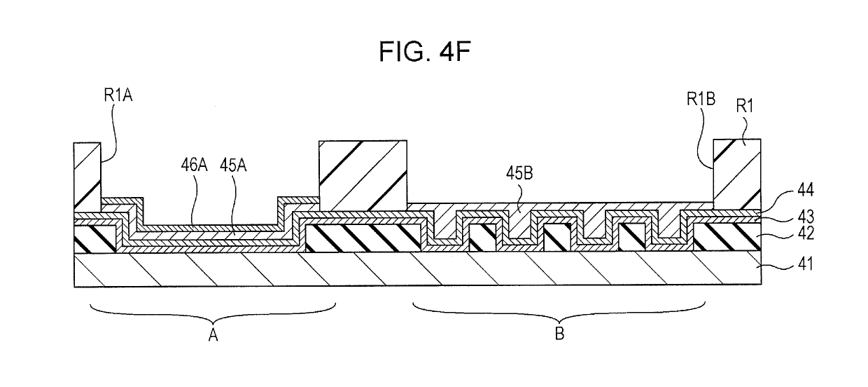

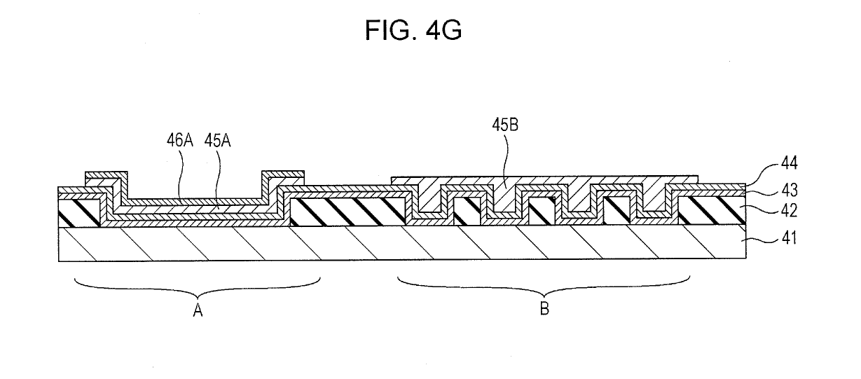

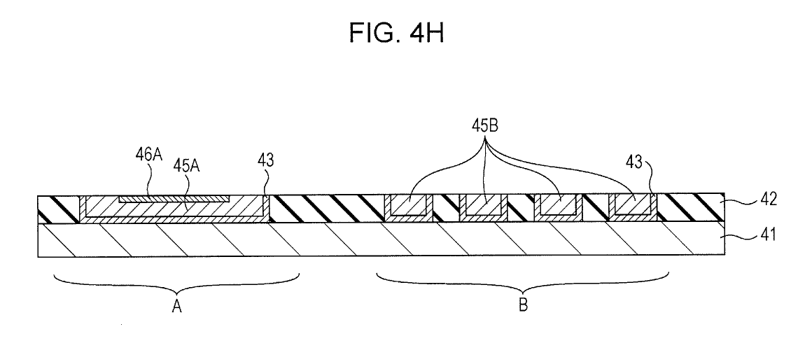

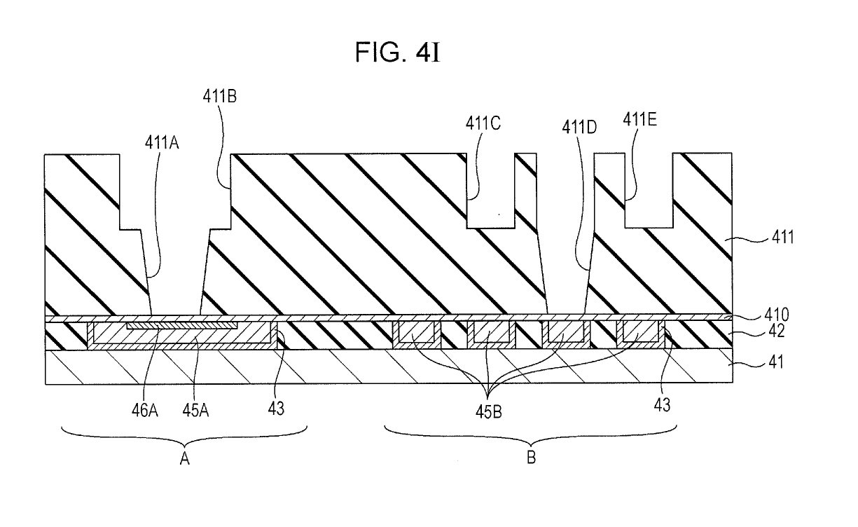

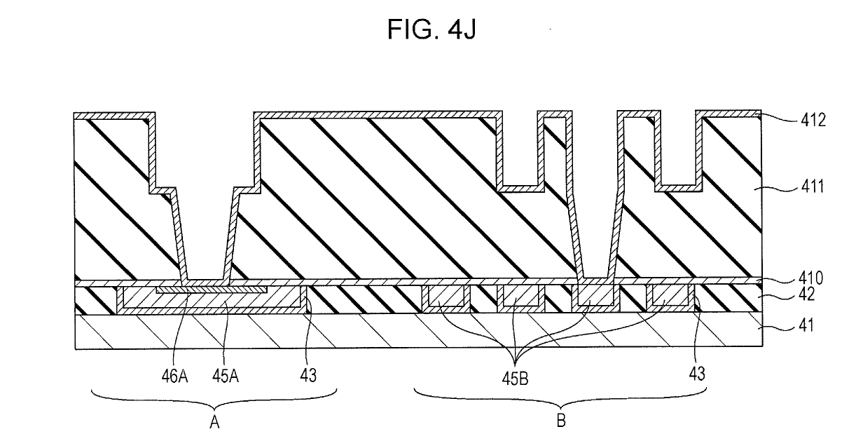

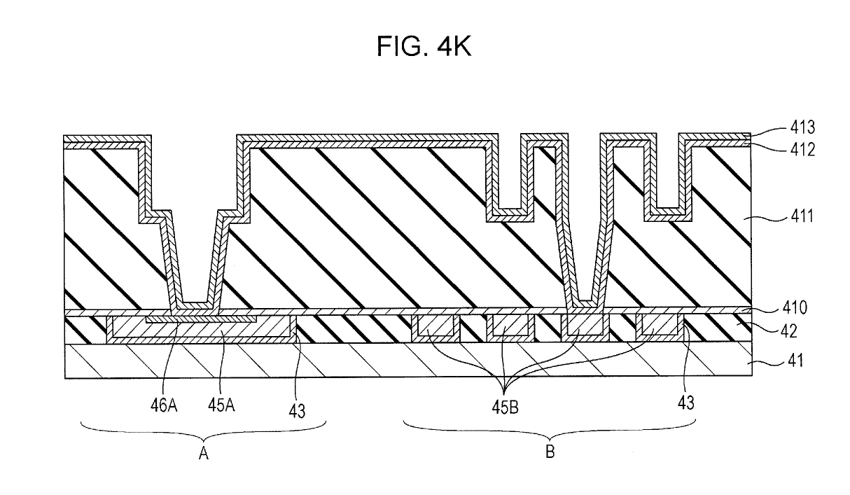

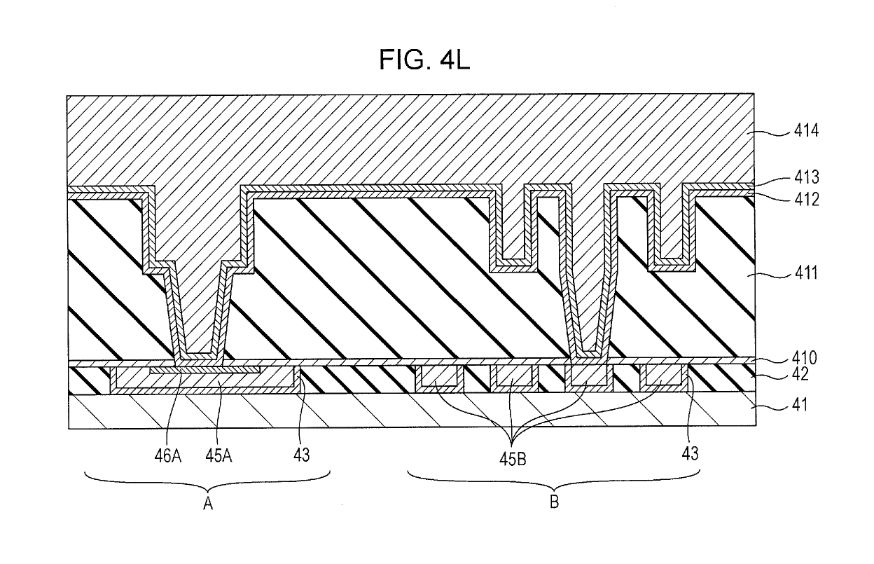

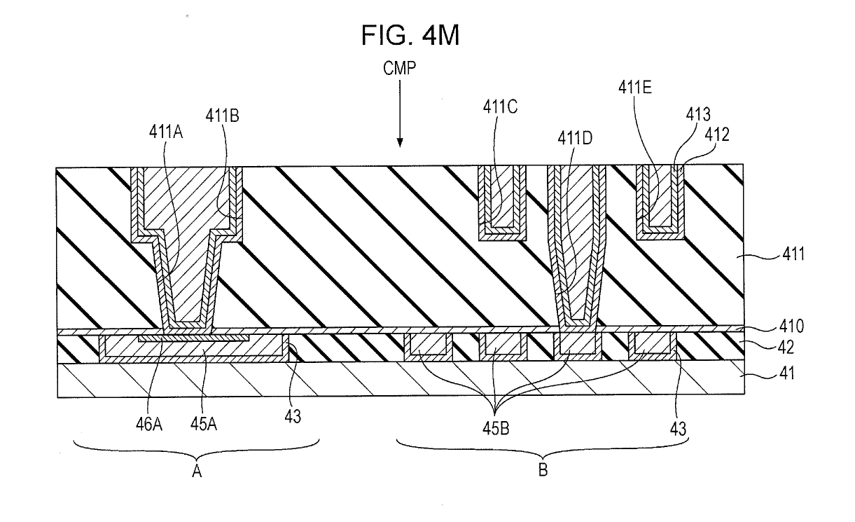

A first embodiment will be described below with reference to cross-sectional views of FIGS. 4A to 4H.

Referring to FIG. 4A, an insulating film 42 composed of, for example, a resin or silicon oxide is formed on a substrate 41 composed of, for example, a resin, glass, or silicon. A first interconnection trench 42A having a depth-to-width ratio of 1/5 or less is formed in a first region A of the insulating film 42. Second interconnection trenches 42B each having a depth-to-width ratio exceeding 1/5 are formed in a second region B of the insulating film 42.

For example, the first interconnection trench 42A has a depth of 1 μm, a width of 5 μm, and a depth-to-width ratio of 1/5. For example, the second interconnection trenches 42B each have a depth of 1 μm and a width of 1 μm and are arranged at a pitch of 2.0 μm to form a line-and-space pattern in the second region B.

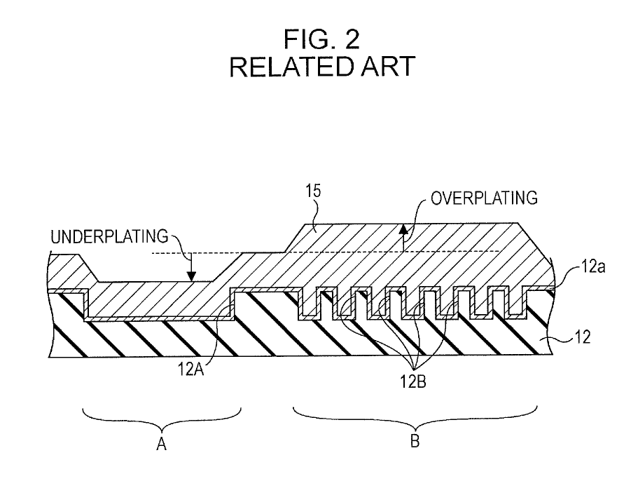

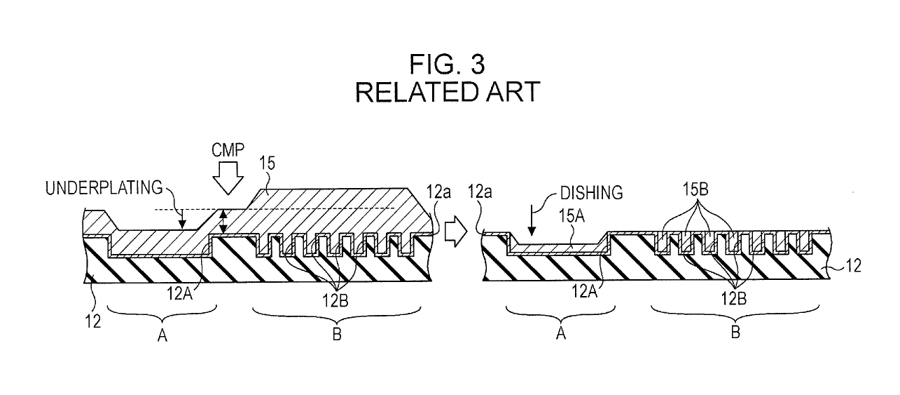

In this example illustrated in FIG. 4A, the width (length in the direction of the arrangement of the trenches) of the second region B is 200 μm. The length of each of the first interconnection trench 42A and the second interconnection trenches 42B in the extension direction is 1.5 mm. However, the embodiments are not limited to the specific structure. The first interconnection trench 42A has a depth-to-width ratio of 1/5, which is 1/5 or less, and each of the second interconnection trenches 42B has a depth-to-width ratio of 1/1, which exceeds 1/5. In the case where the first interconnection trench 42A and the second interconnection trenches 42B are filled with Cu by electroplating, underplating occurs in the first region A, and overplating occurs in the second region B, as illustrated in FIGS. 2 and 3.

In a state illustrated in FIG. 4A, a barrier metal film 43 formed of a high-melting-point metal film, e.g., a Ti or Ta film, a conductive nitride film, e.g., a TaN or TiN film, or a laminated film including these films, is formed by typically a sputtering method or a CVD method on the insulating film 42 to cover the first interconnection trench 42A and the second interconnection trenches 42B, the barrier metal film 43 having a thickness of 5 nm to 50 nm and preferably 10 nm to 25 nm. A Cu seed layer 44 is formed by typically a sputtering method or an electroless plating method on the barrier metal film 43, the Cu seed layer 44 having a thickness of 10 nm to 200 nm and preferably 50 nm to 100 nm.

As illustrated in FIG. 4B, a resist film R1 is formed on the structure illustrated in FIG. 4A so as to be filled into the first interconnection trench 42A and the second interconnection trenches 42B. Then a resist opening portion R1A is formed in the resist film R1 to expose the first interconnection trench 42A in the first region A. Here, the resist opening portion R1A preferably has a size about 10% larger than the first region A where the first interconnection trench 42A is formed, in view of the misregistration of an exposure mask.

In this embodiment, in order to perform the subsequent electroplating step, the Cu seed layer 44 is preferably exposed so as to be energized from a peripheral portion of the substrate 41 (not illustrated). In the case where a structure in which an electrode passing through the resist film R1 is in contact with the Cu seed layer 44 is used in the electroplating step, the formation of an exposed portion of the Cu seed layer 44 located at the peripheral portion of the substrate 41 may be omitted.

As illustrated in FIG. 4C, the structure illustrated in FIG. 4B is immersed in a Cu plating bath, and the Cu seed layer 44 is energized. Thereby, a first Cu layer 45A is formed in the first interconnection trench 42A in the first region A with the resist film R1 as a mask. The first interconnection trench 42A has a depth-to-width ratio of 1/5 or less. Thus, as illustrated in FIGS. 2 and 3, when fine interconnection trenches are simultaneously filled, overplating occurs easily on the fine interconnection trenches. In the case of FIG. 4C, the fine second interconnection trenches 42B are covered with the resist film R1. Thus, the Cu layer is not filled into the second interconnection trenches 42B, thereby not causing disadvantageous overplating.

At the stage illustrated in FIG. 4C, the first Cu layer 45A bulges at its peripheral portion 45a because the first Cu layer 45A is deposited above the upper surface of the insulating film 42. In a main portion 45b where the first interconnection trench 42A is filled, the first Cu layer 45A preferably has a thickness such that the upper surface of the first Cu layer 45A is flush with the upper surface of the insulating film 42.

As illustrated in FIG. 4D in this embodiment, a polishing stopper film 46A is formed on the first Cu layer 45A with the resist film R1 as a mask, the polishing stopper film 46A being composed of a conductive material having higher selectivity for the first Cu layer 45A during subsequent chemical-mechanical polishing of the first Cu layer 45A. In the case where the polishing stopper film 46A is formed by electroless plating, for example, CoWP, NiP, Au, or Ag may be used as a material for the polishing stopper film 46A. In the case where the polishing stopper film 46A is formed by CVD, for example, Ti, Ta, or W may be used.

The polishing stopper film 46A has a thickness of, for example, about 10 nm to about 200 nm and preferably 20 nm to 100 nm.

As illustrated in FIG. 4E, a resist opening portion R1B is formed in the resist film R1 to expose the second interconnection trenches 42B in the second region B while leaving the first region A as it is. Here, the resist opening portion R1B preferably has a size about 10% larger than the second region B in view of the misregistration of an exposure mask.

As illustrated in FIG. 4F, Cu electroplating is performed with the resist film R1 as a mask to fill the second interconnection trenches 42B with a Cu layer 45B in the second region B.

In this embodiment, the first Cu layer 45A is covered with the polishing stopper film 46A in the first region A as has been described above. In the case where the polishing stopper film 46A is particularly composed of, for example, Ti, Ta, or W, the further deposition of Cu does not occur on the polishing stopper film 46A in the electroplating step illustrated in FIG. 4F.

Each of the second interconnection trenches 42B has a depth-to-width ratio of about 1. This value is much larger than 1/5, which is a value serving as an index of the occurrence of overplating. Thus the Cu layer 45B is rapidly filled into the second interconnection trenches 42B. Hence, the thickness of the Cu layer 45B in the second interconnection trenches 42B may be substantially equalized to the thickness of the first Cu layer 45A in the first interconnection trench 42A by adjusting the plating time of electroplating treatment illustrated in FIG. 4F.

As illustrated in FIG. 4G, the resist film R1 is removed. Chemical-mechanical polishing is performed until the surface of the insulating film 42 is exposed, thereby providing an interconnection structure in which the first interconnection trench 42A is filled with the first Cu layer 45A with the barrier metal film 43, the second interconnection trenches 42B are filled with the Cu layer 45B with the barrier metal film 43, and the planarized surfaces of the first Cu layer 45A and the Cu layer 45B are flush with the surface of the insulating film 42, as illustrated in FIG. 4H.

In the structure illustrated in FIG. 4H, the protruding peripheral portion 45a of the first Cu layer 45A is preferentially polished. As a result, the polishing stopper film 46A is not left at the periphery of the first Cu layer 45A. The surface of the first Cu layer 45A is circularly exposed around the polishing stopper film 46A.

In a step illustrated in FIG. 4I, an insulating film 411 composed of an inorganic or organic material is formed on the insulating film 42 with a diffusion barrier film 410 composed of, for example, SiC or SiN. Via holes 411A and 411D configured to expose the lower interconnection patterns of the first Cu layer 45A and the Cu layer 45B, and interconnection trenches 411B, 411C, and 411E are formed in the insulating film 411 by dry etching or photolithography. In the example illustrated in FIG. 4I, the via hole 411A overlaps the interconnection trench 411B.

For example, in the case where the insulating film 411 is a SiO₂ film, a SiC film, or another low-k organic or inorganic film, the via holes 411A and 411D and the interconnection trenches 411B, 411C, and 411E may be formed by dry etching. In the case where the insulating film 411 is a photosensitive permanent resist, the via holes 411A and 411D and the interconnection trenches 411B, 411C, and 411E may be formed by photolithography.

As illustrated in FIG. 4J, a barrier metal film 412, which is typically a high-melting-point metal film composed of, e.g., Ti, Ta, or W, or a conductive film of a nitride thereof, is formed on the structure illustrated in FIG. 4I by, for example, a sputtering method or a CVD method so as to cover surfaces of the via holes 411A and 411D and the interconnection trenches 411B, 411C, and 411E.

As illustrated in FIG. 4K, a conductive Cu seed layer 413 is formed by, for example, a sputtering method, a CVD method, or an electroless plating method on the structure illustrated in FIG. 4J. The structure illustrated in FIG. 4K is immersed in an electroplating bath (not illustrated). The conductive Cu seed layer 413 is energized, so that the via holes 411A and 411D and the interconnection trenches 411B, 411C, and 411E on the insulating film 411 are filled, thereby forming a Cu layer 414 by electroplating as illustrated in FIG. 4L. This electroplating process is typically performed in such a manner that the via holes 411A and 411D and the interconnection trenches 411B, 411C, and 411E are filled upward from the bottom (bottom up) while the formation of voids and seams in the Cu layer 414 is inhibited by the addition of a brightener (also referred to as an accelerator), a suppressant (also referred to as a polymer or suppressor), and a smoothing agent (also referred to as a leveler) to a virgin make-up solution (VMS) containing Cu ions, H₂SO₄, Cl ions, and so forth.

As illustrated in FIG. 4M, the Cu layer 414 is subjected to chemical-mechanical polishing until the upper surface of the insulating film 411 is exposed. Thereby, Cu via plugs 414A and 414D and Cu interconnection patterns 414B, 414C, and 414E are formed of the Cu layer 414 in the via holes 411A and 411D and the interconnection trenches 411B, 411C, and 411E.

As illustrated in FIG. 4N, a diffusion barrier film 415 composed of SiN or SiC is formed as a cap film on the insulating film 411, the diffusion barrier film 415 covering the Cu via plugs 414A and 414D and the Cu interconnection patterns 414B, 414C, and 414E.

In this embodiment, the first Cu layer 45A and the Cu layer 45B are separately formed. This inhibits the problem of the occurrence of overplating and underplating caused when the first Cu layer 45A and the Cu layer 45B are simultaneously formed. Furthermore, the polishing stopper film 46A is formed on the surface of the first Cu layer 45A so as to cover the middle portion of the first Cu layer 45A that is easily polished to cause dishing. Thus, even if chemical-mechanical polishing is performed in the step illustrated in FIG. 4H, the occurrence of dishing in the first Cu layer 45A in the first region A is reliably inhibited.

In this embodiment, the dishing problem is solved. Hence, the first Cu layer 45A and the Cu layer 45B each having a large thickness is not formed, unlike the related art. It is thus possible to solve the problem of a reduction in productivity due to chemical-mechanical polishing over prolonged periods of time and the problem of unnecessary consumption of slurry and metals.

In this embodiment, at the stage illustrated in FIG. 4G, the chemical-mechanical polishing starts at the protruding peripheral portion 45a of the first Cu layer 45A. The protruding peripheral portion 45a is rapidly removed by the polishing. Thus, even if the protruding peripheral portion 45a is formed, the protruding peripheral portion 45a does not cause obstruction to the chemical-mechanical polishing treatment illustrated in FIG. 4G.

### Second Embodiment

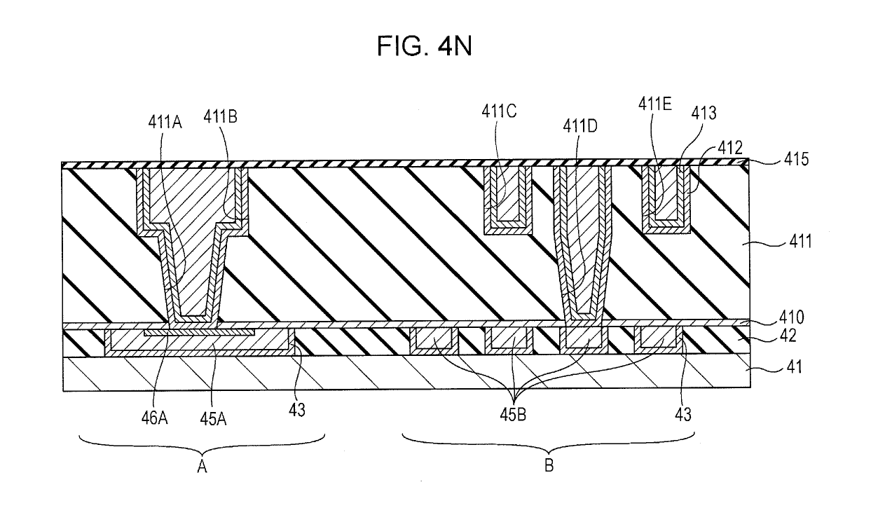

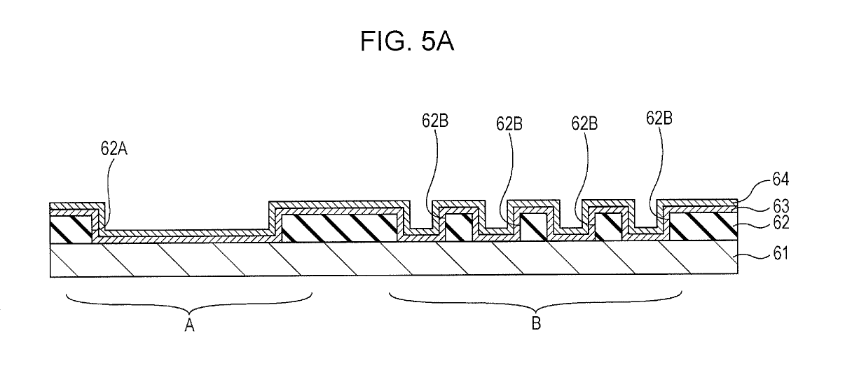

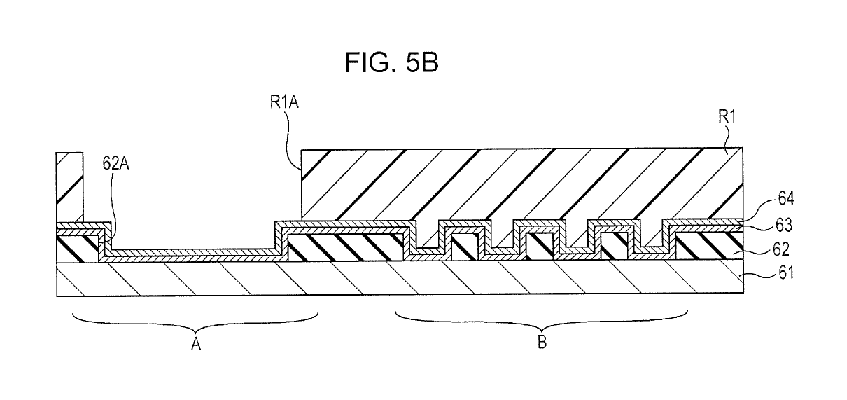

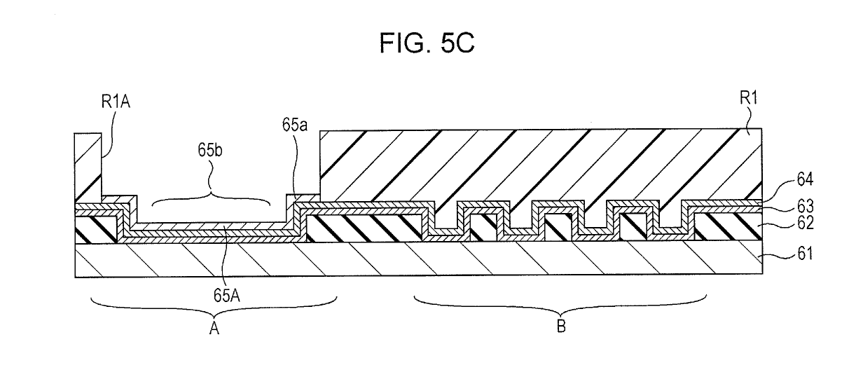

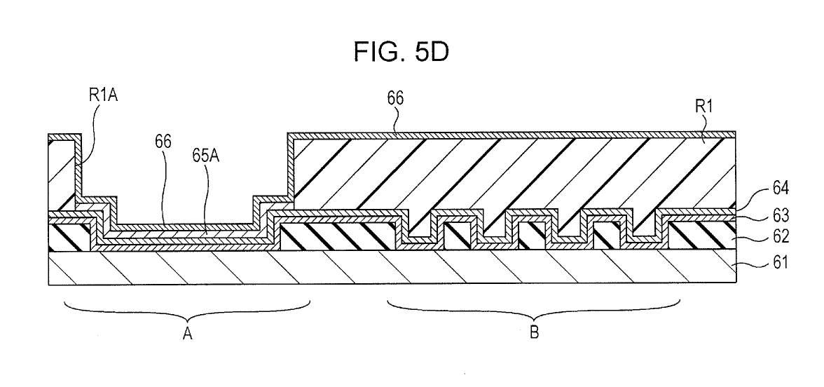

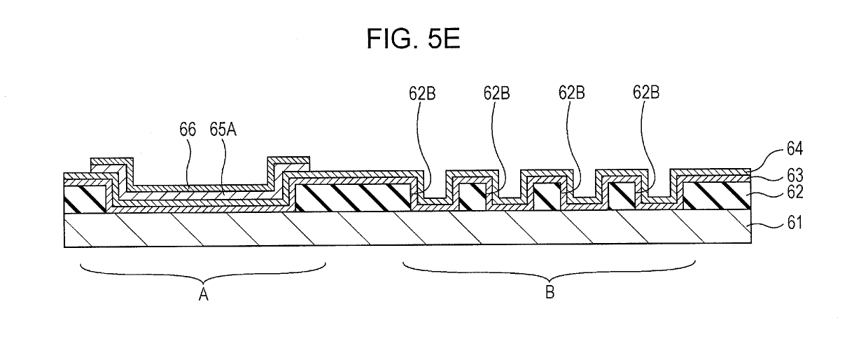

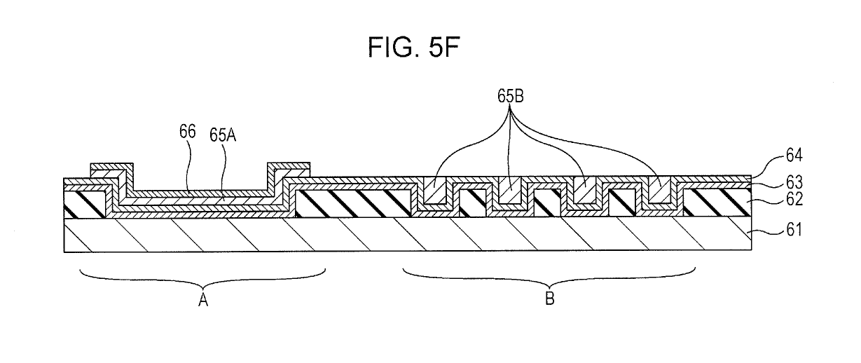

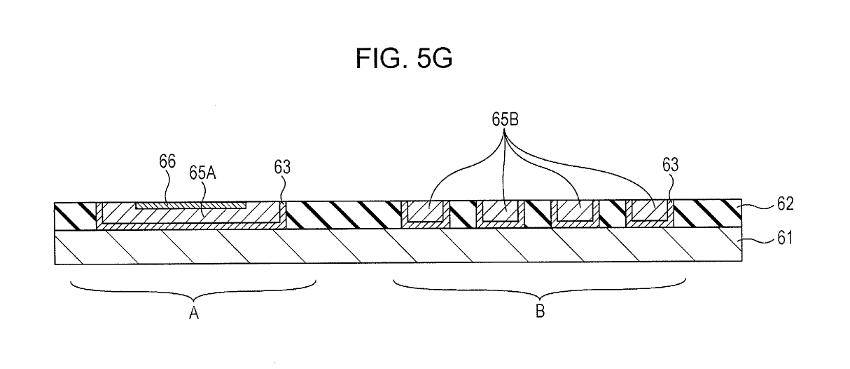

A second embodiment will be described below with reference to cross-sectional views of FIGS. 5A to 5G.

Referring to FIG. 5A, an insulating film 62 composed of, for example, a resin or silicon oxide is arranged on a substrate 61 composed of for example, a resin, glass, or silicon. A first interconnection trench 62A having a depth-to-width ratio of 1/5 or less is formed in a first region A of the insulating film 62. Second interconnection trenches 62B each having a depth-to-width ratio exceeding 1/5 are formed in a second region B of the insulating film 62.

For example, the first interconnection trench 62A has a depth of 1 μm, a width of 7 μm, and a depth-to-width ratio of 1/7. For example, the second interconnection trenches 62B each have a depth of 0.5 μm and a width of 0.5 μm and are arranged at a pitch of 0.5 μm to form a line-and-space pattern in the second region B.

In this example illustrated in FIG. 5A, the width (length in the direction of the arrangement of the trenches) of the second region B is 200 μm. The length of each of the first interconnection trench 62A and the second interconnection trenches 62B in the extension direction is 1.5 mm. However, the embodiments are not limited to the specific structure. The first interconnection trench 62A has a depth-to-width ratio of 1/7, which is 1/5 or less, and each of the second interconnection trenches 62B has a depth-to-width ratio of 1/1, which exceeds 1/5. In the case where the first interconnection trench 62A and the second interconnection trenches 62B are filled with Cu by electroplating, underplating occurs in the first region A, and overplating occurs in the second region B, as illustrated in FIGS. 2 and 3.

In a state illustrated in FIG. 5A, a barrier metal film 63 formed of a high-melting-point metal film, e.g., a Ti or Ta film, a conductive nitride film, e.g., a TaN or TiN film, or a laminated film including these films, is formed by typically a sputtering method or a CVD method on the insulating film 62 to cover the first interconnection trench 62A and the second interconnection trenches 62B, the barrier metal film 63 having a thickness of 5 nm to 50 nm and preferably 10 nm to 25 nm. A Cu seed layer 64 is formed by typically a sputtering method or an electroless plating method on the barrier metal film 63, the Cu seed layer 64 having a thickness of 10 nm to 200 nm and preferably 50 nm to 100 nm.

As illustrated in FIG. 5B, a resist film R1 is formed on the structure illustrated in FIG. 5A so as to be filled into the first interconnection trench 62A and the second interconnection trenches 62B. Then a resist opening portion R1A is formed in the resist film R1 to expose the first interconnection trench 62A in the first region A. Here, the resist opening portion R1A preferably has a size about 10% larger than the first region A where the first interconnection trench 62A is formed, in view of the misregistration of an exposure mask.

Also in this embodiment, in order to perform the subsequent electroplating step, the Cu seed layer 64 is preferably exposed so as to be energized from a peripheral portion of the substrate 61 (not illustrated). In the case where a structure in which an electrode passing through the resist film R1 is in contact with the Cu seed layer 64 is used in the electroplating step, the formation of an exposed portion of the Cu seed layer 64 located at the peripheral portion of the substrate 61 may be omitted.

As illustrated in FIG. 5C, the structure illustrated in FIG. 5B is immersed in a Cu plating bath, and the Cu seed layer 64 is energized. Thereby, a first Cu layer 65A is formed in the first interconnection trench 62A in the first region A with the resist film R1 as a mask. The first interconnection trench 62A has a depth-to-width ratio of 1/5 or less. Thus, as illustrated in FIGS. 2 and 3, when fine interconnection trenches are simultaneously filled, overplating occurs easily on the fine interconnection trenches. In the case of FIG. 5C, the fine second interconnection trenches 62B are covered with the resist film R1. Thus, the Cu layer is not filled into the second interconnection trenches 62B, thereby not causing disadvantageous overplating.

At the stage illustrated in FIG. 5C, the first Cu layer 65A bulges at its peripheral portion 65a because the first Cu layer 65A is deposited above the upper surface of the insulating film 62. In a main portion 65b where the first interconnection trench 62A is filled, the first Cu layer 65A preferably has a thickness such that the upper surface of the first Cu layer 65A is flush with the upper surface of the insulating film 62.

As illustrated in FIG. 5D in this embodiment, a polishing stopper film 66 is formed by a sputtering method on the structure illustrated in FIG. 5C so as to cover the first Cu layer 65A in the first region A and cover the resist film R1, the polishing stopper film 66 being composed of a conductive material having higher selectivity for the first Cu layer 65A during subsequent chemical-mechanical polishing of the first Cu layer 65A. Examples of a material that may be used for the polishing stopper film 66 include CoWP, NiP, Au, Ag, Ti, Ta, and W.

The polishing stopper film 66 has a thickness of, for example, about 10 nm to about 200 nm and preferably 20 nm to 100 nm.

In FIG. 5D, the polishing stopper film 66 covers the resist film R1. In this state, it is not possible to form a resist opening portion configured to expose the second region B by the exposure of the resist film R1 to light. In this embodiment, the entire resist film R1 is thus removed together with the polishing stopper film 66 thereon by a lift-off process as illustrated in FIG. 5E. In this case, the resist opening portion R1A is formed so as to be defined by vertical side walls or side walls having an inverse tapered structure in the step illustrated in FIG. 5B. Portions of the polishing stopper film 66 formed on the side walls of the resist opening portion R1A have a small thickness in the step illustrated in FIG. 5D. Thus, the portions of the polishing stopper film 66 are easily removed by the lift-off process, thereby providing the structure illustrated in FIG. 5E.

As illustrated in FIG. 5F, Cu electroplating is performed on the structure illustrated in FIG. 5E to fill the second interconnection trenches 62B with a Cu layer 65B in the second region B.

In this embodiment, the first Cu layer 65A is covered with the polishing stopper film 66 in the first region A as described above. In the case where the polishing stopper film 66 is particularly composed of, for example, Ti, Ta, or W, the further deposition of Cu does not occur on the polishing stopper film 66 in the electroplating step illustrated in FIG. 5F.

Each of the second interconnection trenches 62B has a depth-to-width ratio of 1. This value is much larger than 1/5, which is a value serving as an index of the occurrence of overplating. Thus the second interconnection trenches 62B are rapidly filled with the Cu layer 65B rapidly. Hence, by adjusting the plating time of electroplating treatment illustrated in FIG. 5F, the electroplating treatment may be performed in such a manner that only the second interconnection trenches 62B are filled with the Cu layer 65B and that substantially no deposition of the Cu layer occurs on a portion other than the second interconnection trenches 62B.

As illustrated in FIG. 5G, chemical-mechanical polishing is performed on the structure illustrated in FIG. 5F until the surface of the insulating film 62 is exposed, thereby providing an interconnection structure in which the first interconnection trench 62A is filled with the first Cu layer 65A with the barrier metal film 63, the second interconnection trenches 62B is filled with the Cu layer 65B with the barrier metal film 63, and the planarized surfaces of the first Cu layer 65A and the Cu layer 65B are flush with the surface of the insulating film 62.

In the structure illustrated in FIG. 5G, the protruding peripheral portion 65a of the first Cu layer 65A is preferentially polished. As a result, the polishing stopper film 66 is not left at the periphery of the first Cu layer 65A. The surface of the first Cu layer 65A is circularly exposed around the polishing stopper film 66.

Also in this embodiment, the first Cu layer 65A and the Cu layer 65B are separately formed. This inhibits the problem of the occurrence of overplating and underplating caused when the first Cu layer 65A and the Cu layer 65B are simultaneously formed. Furthermore, the polishing stopper film 66 is formed on the surface of the first Cu layer 65A so as to cover the middle portion of the first Cu layer 65A that is easily polished to cause dishing. Thus, even if chemical-mechanical polishing is performed in the step illustrated in FIG. 5G, the occurrence of dishing in the first Cu layer 65A in the first region A is reliably inhibited.

Also in this embodiment, the dishing problem is solved. Hence, the first Cu layer 65A and the Cu layer 65B each having a large thickness is not formed, unlike the related art. It is thus possible to solve the problem of a reduction in productivity due to chemical-mechanical polishing over prolonged periods of time and the problem of unnecessary consumption of slurry and metals.

Also in this embodiment, at the stage illustrated in FIG. 5G, the chemical-mechanical polishing starts at the protruding peripheral portion 65a of the first Cu layer 65A. The protruding peripheral portion 65a is rapidly removed by the polishing. Thus, even if the protruding peripheral portion 65a is formed, the protruding peripheral portion 65a does not cause obstruction to the chemical-mechanical polishing treatment illustrated in FIG. 5G.

After the step illustrated in FIG. 5G, also in this embodiment, steps of forming interconnection trenches and via plugs are performed in the same way as illustrated in FIGS. 4I to 4N. These steps are the same as above, and descriptions are not redundantly repeated.

### EXAMPLES

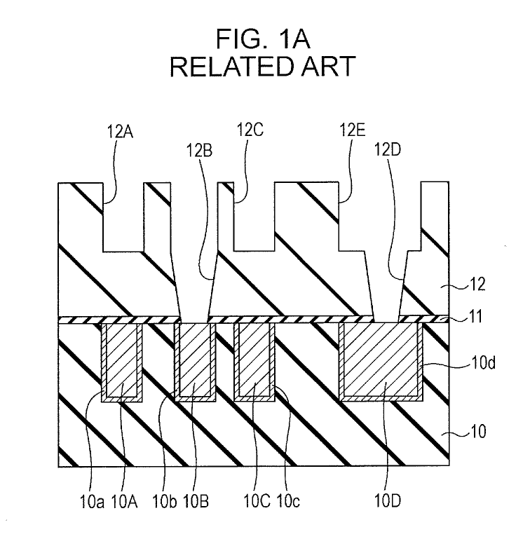

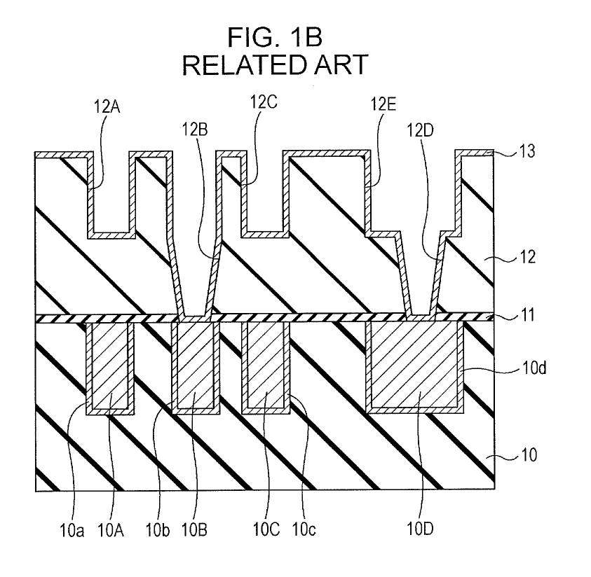

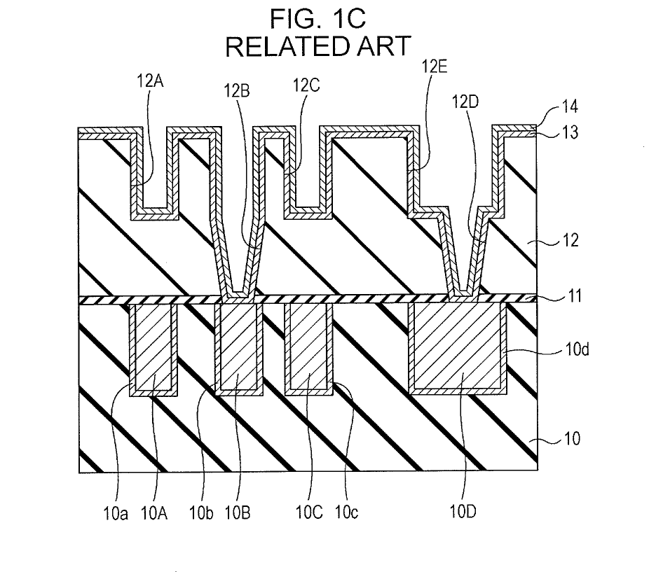

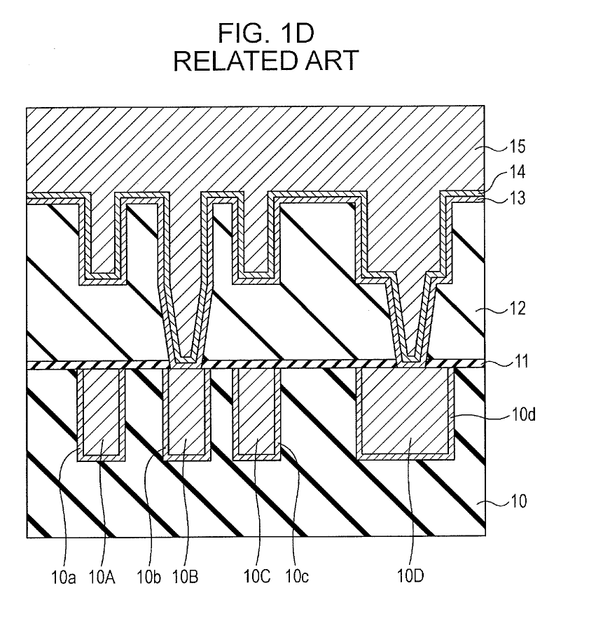

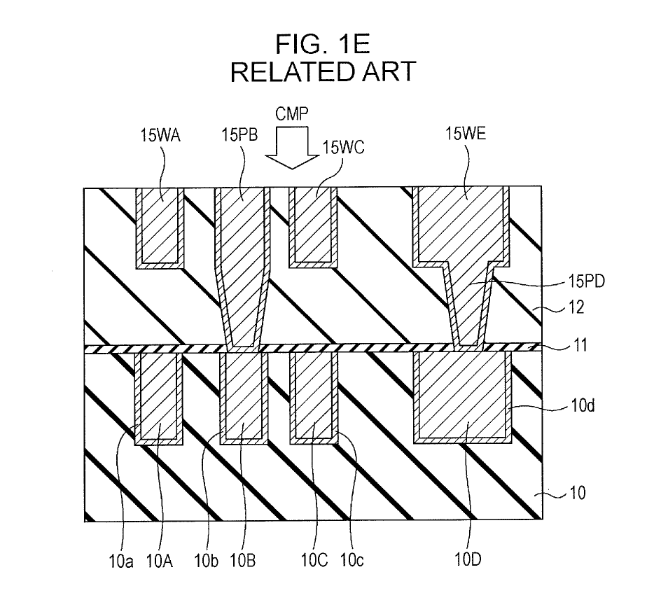

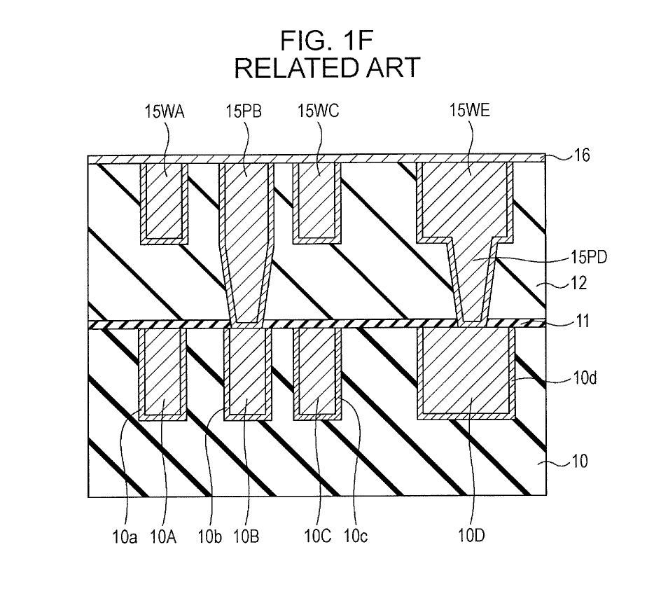

In each case of Examples 1A and 1B corresponding to the first embodiment, Example 2 corresponding to the second embodiment, and a comparative example corresponding to the process illustrated in FIGS. 1A to 1D, the electroplating of a Cu layer and chemical-mechanical polishing are actually performed. The thickness of the Cu layer in a field portion and the amount of underplating before the chemical-mechanical polishing are measured. Furthermore, the amount of dishing after the chemical-mechanical polishing is measured. The measurement results will be described below.

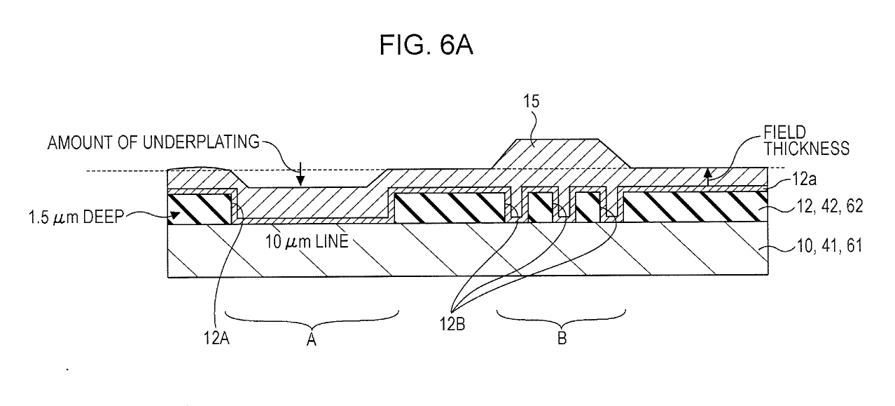

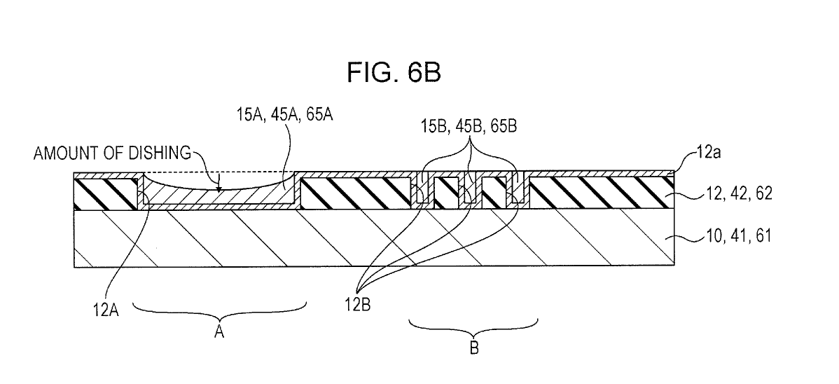

Here, the field portion indicates a flat portion illustrated in FIG. 6A. For example, in the case of the embodiment illustrated in FIGS. 4A to 4N, the field portion indicates a flat portion of the insulating film 42 located between the first interconnection trench 42A and the second interconnection trenches 42B. The amount of underplating indicates the depth of the recess of the surface of the first Cu layer 45A formed in the first region A with respect to the surface of the Cu layer in the field portion. The amount of dishing indicates the depth of the recess of the first Cu layer 45A formed in the first region A with respect to the surface of an insulating film 12a after chemical-mechanical polishing as illustrated in FIG. 6B. In FIGS. 6A and 6B, elements are designated using reference numerals corresponding to those in FIGS. 2 and 3. Descriptions in FIGS. 6A and 6B also hold for the first and second embodiments. The insulating film or substrate 10 corresponds to the substrate 41 illustrated in FIGS. 4A to 4N or the substrate 61 illustrated in FIGS. 5A to 5G. The insulating film 12 corresponds to the insulating film 42 illustrated in FIGS. 4A to 4N or the insulating film 62 illustrated in FIGS. 5A to 5G. The Cu layer 15 formed in the first region A corresponds to first Cu layer 45A illustrated in FIGS. 4A to 4N or first Cu layer 65A illustrated in FIGS. 5A to 5G. The Cu layer 15 formed in the second region B corresponds to the Cu layer 45B illustrated in FIGS. 4A to 4N or the Cu layer 65B illustrated in FIGS. 5A to 5G. In FIGS. 6A and 6B, the lower insulating film 10 or the substrate is located below the insulating film 12, in response to the related art illustrated in FIGS. 1A to 1F.

In each case of Examples 1 and 2 and the comparative example, the insulating film 12 is formed on the lower insulating film 10 so as to have a thickness of 1.5 μm. Each of the interconnection trenches 12A, 42A, and 62A is formed so as to have a depth of 1.5 μm and a width of 10 μm. Each of the interconnection trenches 12B, 42B, and 62B is formed so as to have a depth of 1.5 μm and a width of 1 μm.

The second region B has a width of 200 μm. In the second region B, 100 Cu layers 45B are arranged. Each of the first region A and the second region B has a length of 1.5 mm in the direction perpendicular to the paper plane.

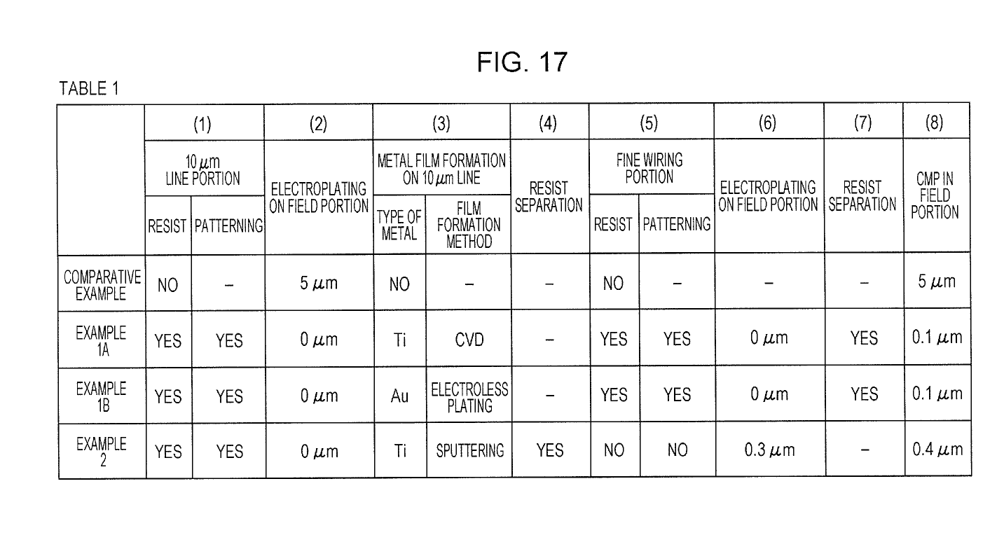

Table 1 illustrated in FIG. 17 summarizes experimental conditions of examples.

In Table 1 illustrated in FIG. 17, “10 μm LINE PORTION” in item (1) indicates in a 10-μm-line portion, i.e., in the first region A, whether a resist film is used or not when Cu electroplating is performed and whether the resist film is patterned or not. “ELECTROPLATING ON FIELD PORTION” in item (2) indicates the thickness of a film formed by the electroplating in the field portion as illustrated in FIG. 6A. “METAL FILM FORMATION ON 10 μm LINE” in item (3) indicates the presence or absence of a metal film serving as a polishing stopper on the Cu layer in the first region A, the type of metal film, and a film formation method. “RESIST SEPARATION” in item (4) indicates whether a resist film is separated or not after Cu electroplating in the first region A and before electroplating in the second region B. “FINE WIRING PORTION” in item (5) indicates in a fine wiring portion, i.e., in the second region B, whether a resist mask is used or not when Cu electroplating is performed, and whether the resist mask is patterned to form a resist window or not. “ELECTROPLATING ON FIELD PORTION” in item (6) indicates the thickness of a film formed by the electroplating in the field portion when Cu electroplating in the second region B is performed. “RESIST SEPARATION” in item (7) indicates whether the resist film used as a mask is separated or not after Cu electroplating on the second region B. “CMP IN FIELD PORTION” in item (8) indicates the amount of the field portion polished by chemical-mechanical polishing.

For example, in the comparative example described in Table 1 illustrated in FIG. 17, no resist mask is used for Cu electroplating on the 10-μm-line portion (first region A) or Cu electroplating on the fine wiring portion (second region B), so “NO” is indicated in the “RESIST” column in item (1) and the “RESIST” column in item (5). Thus, the patterning and separation of a resist are not performed, so “-” (not applicable) is indicated in each of the “RESIST SEPARATION” columns in items (4) and (7). Furthermore, Cu electroplating is performed without a resist mask. Thus, in the comparative example, “5 μm” is indicated in the “ELECTROPLATING ON FIELD PORTION” column in item (2), which indicates the formation of a 5-μm-thick Cu film in the field portion. In the comparative example, the Cu electroplating is simultaneously performed in the first region A and the second region B. In item (6), in order to avoid duplication, the thickness of the Cu film formed by the electroplating on the field portion is not repeatedly described. In the comparative example, “5 μl” is indicated in the “CMP IN FIELD PORTION” column in item (8). That is, in this field portion, the 5-μm-thick film formed by the electroplating is removed by chemical-mechanical polishing.

In Example 1A in Table 1 illustrated in FIG. 17, as illustrated in FIGS. 4B and 4C, the resist film R1 is used and patterned to form the resist opening portion R1A when the first Cu layer 45A is formed in the first region A by electroplating, so “YES” is indicated in each of the “RESIST” and “PATTERNING” columns in item (1). In Example 1A, in the electroplating step illustrated in FIG. 4C, the field portion is covered with the resist film R1 and thus is not subjected to electroplating, so “0 μm” is indicated in item (2). In Example 1A, the polishing stopper film 46A composed of Ti is formed, so “Ti” is indicated in the “TYPE OF METAL” column in item 3, and “CVD” is indicated in the “FILM FORMATION METHOD” column. In Example 1A, electroplating in the first region A and electroplating in the second region B are both performed with the resist film R1, so “-” (not applicable) is indicated in the “RESIST SEPARATION” column in item (4). In Example 1A, Cu electroplating in the second region B is performed on the resist opening portion R1B of the resist film R1, so “YES” is indicated in the “RESIST” column in item (5), and “YES” is indicated in the “PATTERNING”. In Example 1A, the field portion is covered with the resist film R1 and thus is not subjected to electroplating, so “0 μm” is indicated in item (6). After electroplating in the second region B, the resist film R1 is separated in the step illustrated in FIG. 4G, so “YES” is indicated in the “RESIST SEPARATION” in item (7). In the chemical-mechanical polishing treatment illustrated in FIG. 4H, the 100-nm-thick Cu seed layer 44 and the barrier metal film 43 located below the Cu seed layer 44 in the field portion are both removed, so “0.1 μm” is indicated in item (8). This includes the amount of the barrier metal film polished.

Example 1B in Table 1 illustrated in FIG. 17 is similar to Example 1A. A Au film formed by electroless plating is used as the polishing stopper film 46A, so “Au” is indicated in the “TYPE OF METAL” column in item (3), and “ELECTROLESS PLATING” is indicated in the “FILM FORMATION METHOD” column.

Example 2 in Table 1 illustrated in FIG. 17 corresponds to the second embodiment illustrated in FIGS. 5A to 5G. In the steps illustrated in FIGS. 5B and 5C, Cu electroplating is performed in the first region A with the resist film R1 serving as a mask to form the first Cu layer 65A. Next, in the step illustrated in FIG. 5D, the metal film 66 serving as a polishing stopper is formed by sputtering. In the step illustrated in FIG. 5E, the resist film R1 is removed together with the metal film 66 located on the resist film R1 by a lift-off process. In the step illustrated in FIG. 5F, Cu electroplating is performed without a resist film to fill the second interconnection trenches 62B in the second region B with the Cu layer 65B. In this case, the electroplating is stopped when the second interconnection trenches 62B are filled with the Cu layer 65B. Finally, in the step illustrated in FIG. 5G, the Cu layer in the field portion is removed by chemical-mechanical polishing, thereby providing a planarized interconnection structure.

Thus, in Table 1 illustrated in FIG. 17, “YES” is indicated in each of the “RESIST” and “PATTERNING” columns in item (1) similarly to Examples 1A and 1B. In item (3), “Ti” is indicated in the “TYPE OF METAL” column, and “sputtering” is indicated in the “FILM FORMATION METHOD” column. In Example 2, the resist film R1 is removed by the lift-off process in the step illustrated in FIG. 5E, so “YES” is indicated in the “RESIST SEPARATION” column in item (4). The electroplating in the second region B is performed without the resist film as illustrated in FIG. 5F, so “NO” is indicated in each of the “RESIST” and “PATTERNING” columns in item (5). In Example 2, the electroplating is performed without the resist mask in such a manner that the second interconnection trenches 62B are filled in the second region B. Thus, a slight deposition of Cu occurs in the field portion, so “0.3 μm” is indicated in the “ELECTROPLATING IN FIELD PORTION” column in item (6). In Example 2, the electroplating is performed on the second region B without the resist mask, so “-” (not applicable) is indicated in the “RESIST SEPARATION” in item (7). In the step illustrated in FIG. 5G, the Cu film formed by the electroplating in the field portion is removed together with the Cu seed layer 44 and the barrier metal film located below the Cu film, so the amount of the field portion polished is “0.4 μm”.

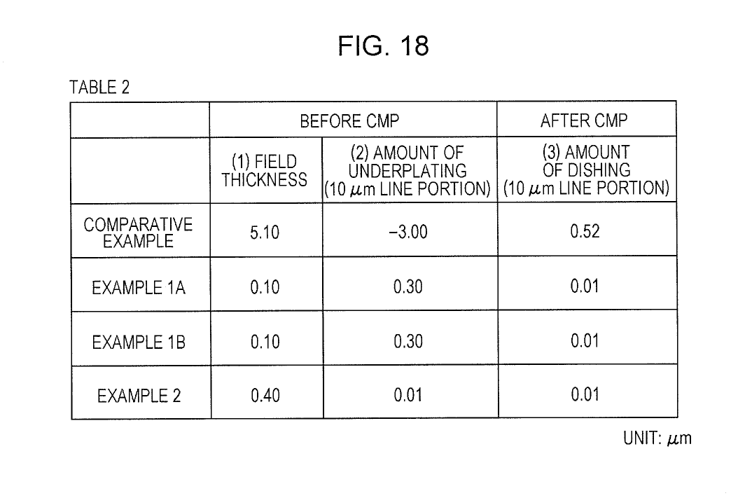

Table 2 illustrated in FIG. 18 describes the evaluation results of these experiments.

Referring to Table 2 illustrated in FIG. 18, in the comparative example, before the chemical-mechanical polishing, i.e., at the state illustrated in FIG. 6A, the field thickness is 5.10 and the amount of underplating is −3.00 μm. After the chemical-mechanical polishing, i.e., at the state illustrated in FIG. 6B, the amount of dishing in the 10-μm-line portion is 0.52

In Example 1A, before the chemical-mechanical polishing, i.e., at the state illustrated in FIG. 6A, the field thickness is reduced to 0.10 μm, and the amount of underplating is also reduced to 0.30 μm. After the chemical-mechanical polishing, i.e., at the state illustrated in FIG. 6B, the amount of dishing in the 10-μm-line portion is reduced to 0.01 μm, which is substantially zero. The same is true for Example 2B.

In Example 2, the field thickness is 0.40 μm, and the amount of underplating is 0.01 μm. Also in this case, the amount of dishing is reduced to 0.01 μm.

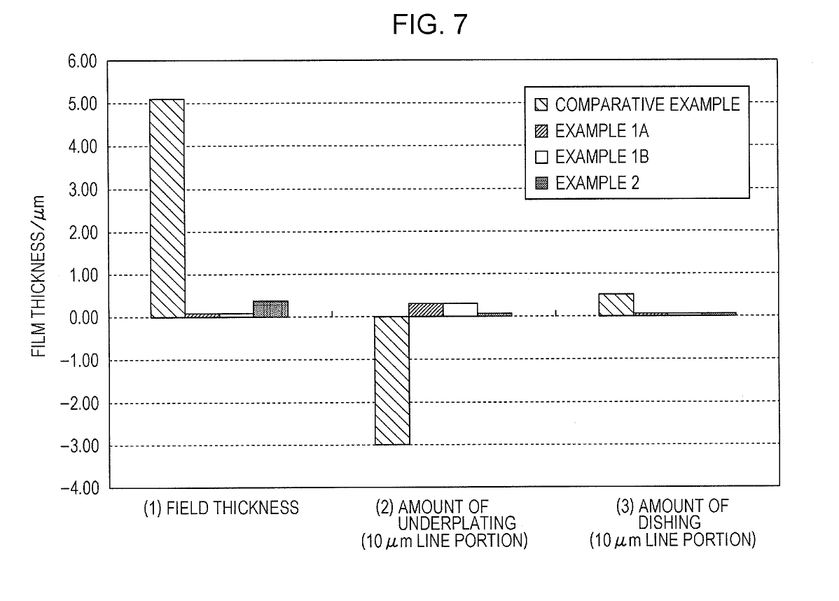

FIG. 7 is a graph that visually summarizes the results described in Table 2. In FIG. 7, the vertical axis represents the field thickness, the amount of underplating, or the amount of dishing.

Referring to FIG. 7, in the comparative example, the field thickness, the amount of underplating, and the amount of dishing are large. This indicates typical problems caused when Cu electroplating is simultaneously performed on the first region A and the second region B.

In each of Examples 1A and 1B, the resist film is used, and optimal Cu electroplating is separately performed for the first region A and the second region B. The field thickness may be suppressed to the contribution just for the 100-nm-thick Cu seed layer.

In particular, in Examples 1A and 1B in which the polishing stopper films 46A are formed, the amount of dishing may be substantially zero. In Example 2, while the field thickness is slightly increased, the amount of underplating may be substantially zero. Furthermore, the amount of dishing may be reduced to substantially zero by the formation of the polishing stopper film 66, similarly to Example 1A or 1B.

In Example 1A, the Ti film is formed on the resist film by CVD with TiCl₄, tetrakisdimethylaminotitanium (TDMAT), or tetrakisdimethylaminotitanium (TDEAT) as a raw material at 300° C. to 500° C. for 20 to 300 seconds (depending on thickness) while promoting the reaction with a plasma.

### Third Embodiment

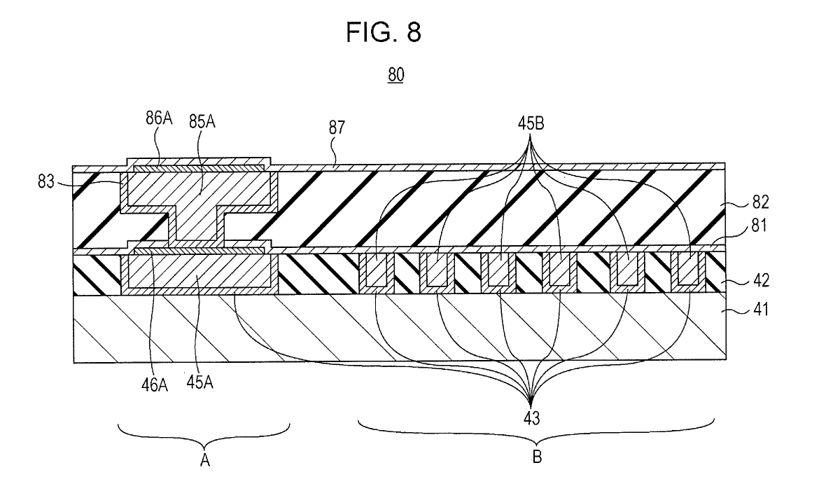

FIG. 8 is a cross-sectional view illustrating an exemplary multilayer circuit board 80 according to a third embodiment. In FIG. 8, elements described in the foregoing embodiments are designated using the corresponding reference numerals, and descriptions are not redundantly repeated.

Referring to FIG. 8, the multilayer circuit board 80 has the interconnection structure illustrated in FIG. 4H. A cap film 81 composed of SiC is formed on the insulating film 42 illustrated in FIG. 4H so as to cover the first Cu layer 45A with the polishing stopper film 46A and so as to cover the Cu layer 45B. An interlayer dielectric film 82 described below is formed on the cap film 81.

A via hole corresponding to the first region A is formed in the interlayer dielectric film 82 so as to expose the interconnection trench and the polishing stopper film 46A. The interconnection trench and the via hole are filled with a Cu layer 85A, thereby establishing electrical connection between the interconnection pattern formed of the Cu layer 85A and the interconnection pattern formed of the first Cu layer 45A.

In the example illustrated in FIG. 8, the Cu layer 85A includes a polishing stopper film 86A on a surface thereof (excluding the peripheral portion), the polishing stopper film 86A being the same as the polishing stopper film 46A. The polishing stopper film 86A is covered with a SiC cap film 87 formed on the interlayer dielectric film 82.

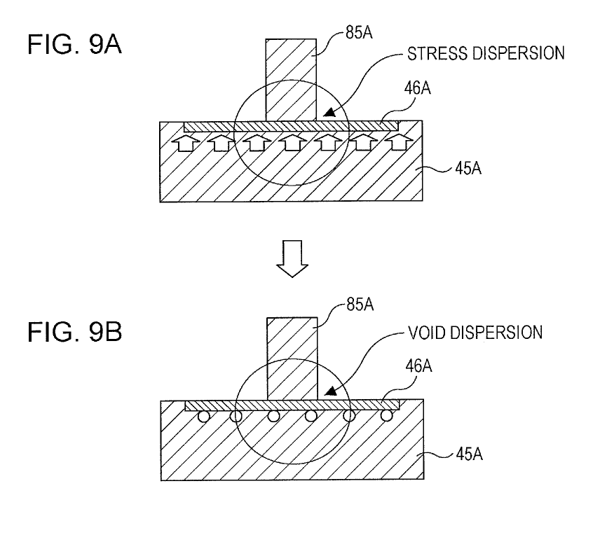

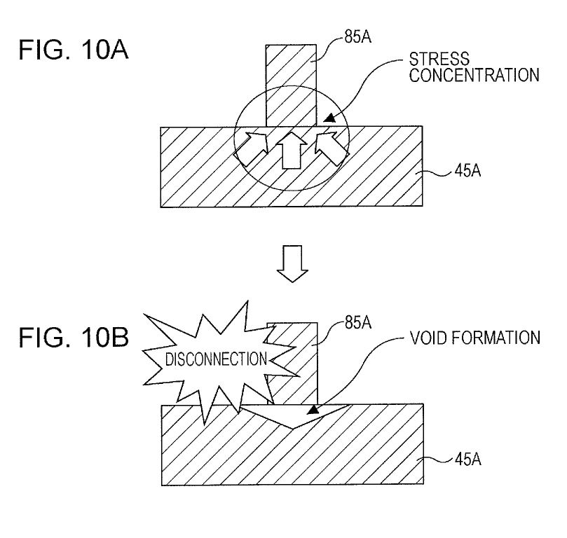

In this structure, an end of a via plug formed of the Cu layer 85A is in contact with the polishing stopper film 46A composed of, for example, CoWP, NiP, Au, Ag, Ti, Ta, or W as illustrated in FIG. 9A which is an enlarged view. In this structure, even if a stress is applied to the via plug, the stress is dispersed along the polishing stopper film 46A as indicated by arrows. As a result, if stress migration occurs, formed voids are dispersed below the polishing stopper film 46A. The structure inhibits the concentration of voids in a region directly below the via plug due to stress migration that is expected to occur in the hypothetical case where the polishing stopper film 46A is not formed as illustrated in FIGS. 10A and 10B. This effectively inhibits the occurrence of disconnection.

In the multilayer circuit board 80 illustrated in FIG. 8, in the case where the contact resistance between the via plug formed of the Cu layer 85A and the first Cu layer 45A is particularly reduced, a structure may be used in which the via plug formed of the Cu layer 85A is in direct contact with a surface of the first Cu layer 45A through an opening portion formed in the polishing stopper film 46A.

Furthermore, the structure illustrated in FIG. 8 may be repeatedly formed to provide a circuit board having a greater number of layers.

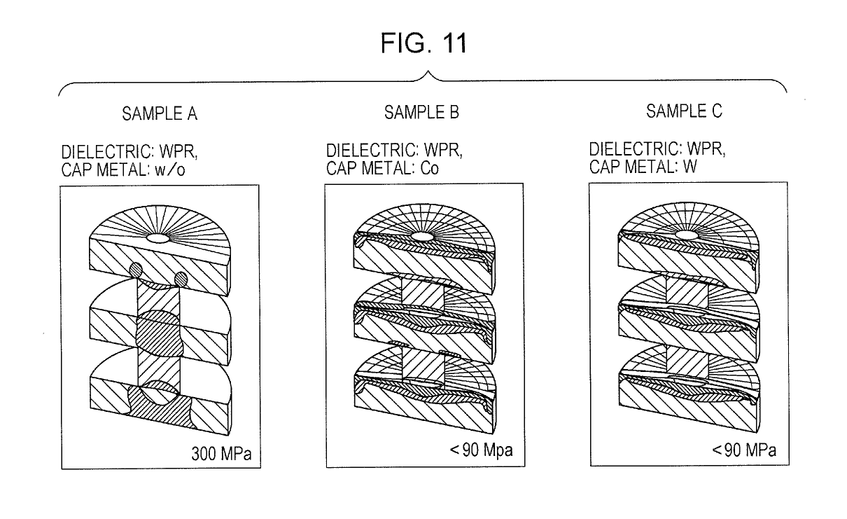

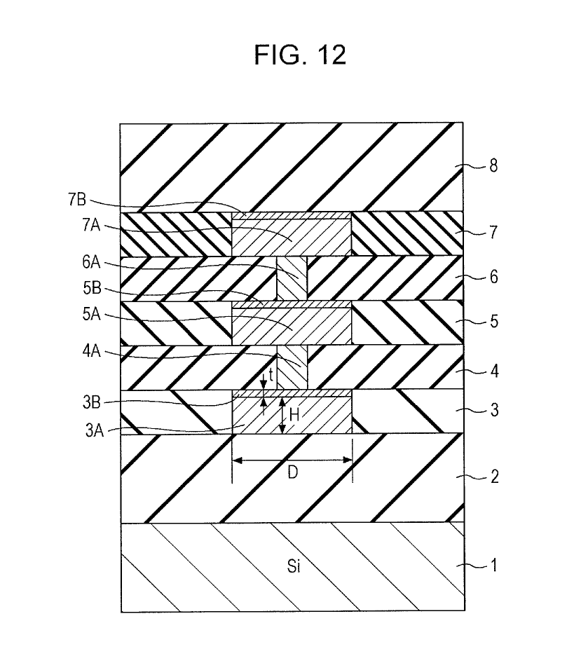

FIG. 11 illustrates the simulation results of stresses accumulated in via plugs of a model structure illustrated in FIG. 12 when a thermal cycling test is performed 1000 cycles in the temperature range of −55° C. to +125° C.

First, referring to FIG. 12, a similar interlayer dielectric film 3 is arranged on a silicon substrate 1 having an elastic modulus of 130 GPa, a Poisson's ratio of 0.28, and a thermal expansion coefficient of 2.6 ppmK⁻¹ with an interlayer dielectric film 2 having an elastic modulus of 2.5 GPa, a Poisson's ratio of 0.25, and a thermal expansion coefficient of 54 ppmK⁻¹. A land 3A formed of a Cu pattern having a width W or diameter D of 10 μm to 25 μm and a height H of 2 μm is arranged in the interlayer dielectric film 3. A metal film 3B composed of cobalt (Co) or tungsten (W) and having a thickness t of 100 nm and a width equal to the width W is arranged on the land 3A in response to the polishing stopper film 46A. Here, the Cu film has an elastic modulus of 127.5 GPa, a Poisson's ratio of 0.33, and a thermal expansion coefficient of 16.6 ppmK⁻¹. The Co film has an elastic modulus of 211 GPa, a Poisson's ratio of 0.31, and a thermal expansion coefficient of 12.6 ppmK⁻¹. The W film has an elastic modulus of 411 GPa, a Poisson's ratio of 0.28, and a thermal expansion coefficient of 4.5 ppmK⁻¹.

A 3-μm-thick interlayer dielectric film 4 similar to the interlayer dielectric film 2 is arranged on the interlayer dielectric film 3. A Cu via plug 4A having a diameter of 3 μm to 5 μm and a height of 3 μm is arranged in the interlayer dielectric film 4 so as to be in contact with the metal film 3B. The interlayer dielectric films 2 to 4 and interlayer dielectric films 5 to 8 described below correspond to films composed of a photosensitive insulating material (trade name: WPR, manufactured by JSR Corporation). In this embodiment, however, the interlayer dielectric films 2 to 8 are not limited to the films composed of a photosensitive insulating material (trade name: WPR, manufactured by JSR Corporation). For example, the use of a low-dielectric-constant film composed of nano-clustering silica (NCS, porous silica) also provides the same results as those illustrated in FIG. 11.

The interlayer dielectric film 5 having a thickness of 2 μm is arranged on the interlayer dielectric film 4. A land 5A similar to the land 3A and having the same dimensions as the land 3A is arranged in the interlayer dielectric film 5 so as to be in contact with the Cu via plug 4A. A metal film 5B similar to the metal film 3B and having the same dimensions as the metal film 3B is arranged on the land 5A.

The interlayer dielectric film 6 having a thickness of 3 μm is arranged on the interlayer dielectric film 5. A Cu via plug 6A similar to the Cu via plug 4A and having the same dimensions as the Cu via plug 4A is arranged in the interlayer dielectric film 6 so as to be in contact with the metal film 5B that covers a surface of the land 5A.

The interlayer dielectric film 7 having a thickness of 2 μm is arranged on the interlayer dielectric film 6. A land 7A similar to the land 3A and having the same dimensions as the land 3A is arranged in the interlayer dielectric film 7 so as to be in contact with the Cu via plug 6A. A metal film 7B similar to the metal film 3B and having the same dimensions as the metal film 5B is arranged on the land 7A.

The similar interlayer dielectric film 8 having a thickness of 10 μm is arranged on the interlayer dielectric film 7.

Referring to FIG. 11 again, sample A is a control sample, and the metal films 3B, 5B, and 7B are omitted in the model structure illustrated in FIG. 12. In the case of sample B, Co films are arranged as the metal films 3B, 5B, and 7B in the model structure illustrated in FIG. 12. In the case of sample C, W films are arranged as the metal films 3B, 5B, and 7B in the model structure illustrated in FIG. 12. In FIG. 11, lighter-colored portions indicate higher stress accumulation. Dark-colored portions indicate low stress accumulation. Note that in the model structure illustrated in FIG. 12, each of the metal films 3B, 5B, and 7B has a higher elastic modulus than the Cu lands 3A, 5A, and 7A and the Cu via plugs 4A and 6A.

In the model structure illustrated in FIG. 12, barrier metal films (not illustrated) are arranged on the Cu lands 3A, 5A, and 7A and the Cu via plugs 4A and 6A. Each of the barrier metal films has a small thickness of at most 5 nm to 20 nm. Thus, the effects of the barrier metal films are negligible in the stress simulation illustrated in FIG. 11.

Referring to FIG. 11, in the case of the control sample A, while the stress accumulation in the lands 3A, 5A, and 7A is low, stress concentration occurs in the Cu via plugs 4A and 6A at a stress of about 300 MPa. In contrast, in each of the cases of samples B and C in which the metal films 3B, 5B, and 7B are arranged, stress accumulated in each of the Cu via plugs 4A and 6A is less than 90 Ma, and stress concentration occurs mainly in the high-elastic-modulus metal films 3B, 5B, and 7B.

The model structure illustrated in FIG. 12 was actually produced. The resulting model structure was subjected to 1000 cycles of a thermal cycling test in the temperature range of −55° C. to +125° C. For control samples that did not include the metal film 3B, 5B, or 7B, disconnection occurred in 18 samples out of 20. In contrast, for samples including the metal films 3B, 5B, and 7B composed of Co or W, no disconnection occurred in all 20 samples. In the thermal cycling test, the holding time at −55° C. and 125° C. was 15 minutes.

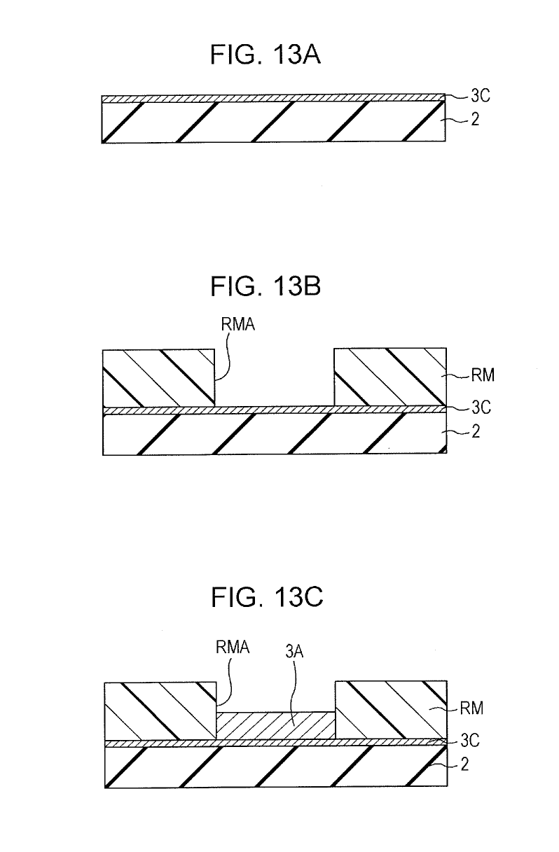

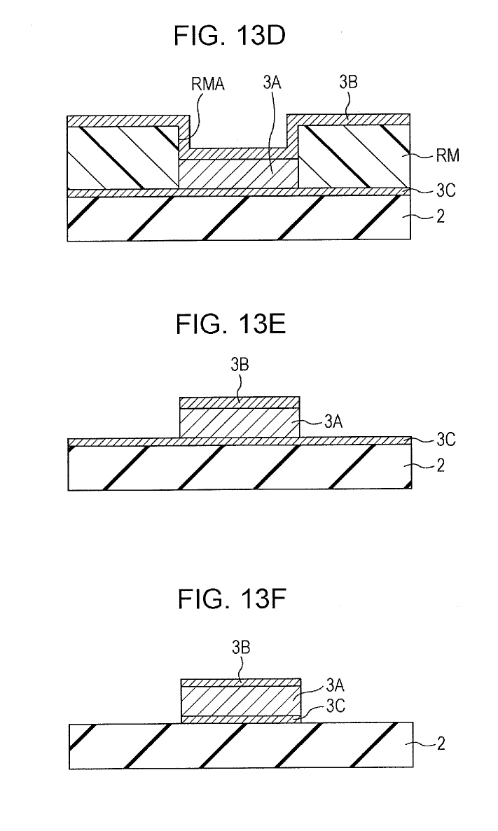

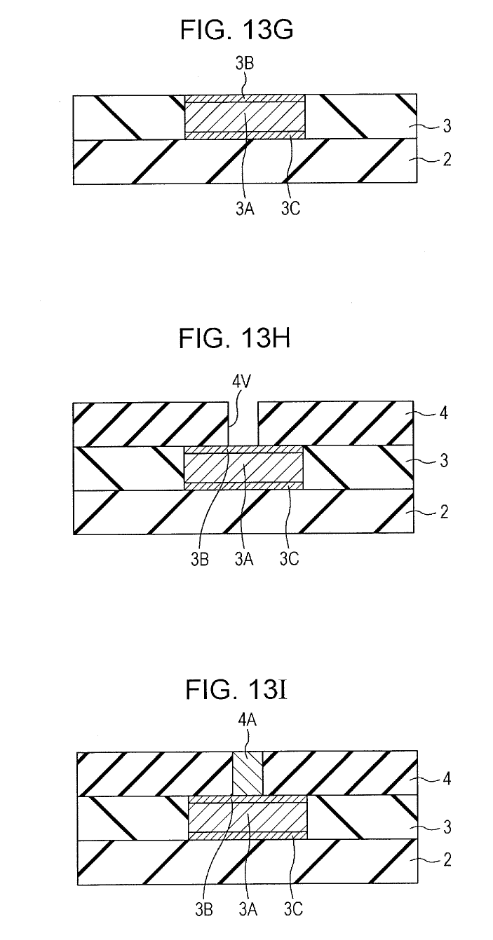

Here, the structure illustrated in FIG. 12 is formed as described below. As illustrated in FIG. 13A, a Cu seed layer 3C is uniformly formed by a sputtering method on the interlayer dielectric film 2. As illustrated in FIG. 13B, a resist pattern RM having a resist opening portion RMA corresponding to the land 3A is formed on the interlayer dielectric film 2. As illustrated in FIG. 13C, electroplating or electroless plating is performed with the resist pattern RM as a mask to form the land 3A. As illustrated in FIG. 13D, the metal film 3B is formed by sputtering on the structure illustrated in FIG. 13C. As illustrated in FIG. 13E, a portion of the metal film 3B other than a portion of the metal film 3B on the land 3A is removed together with the resist pattern RM by a lift-off process. As illustrated in FIG. 13F, an unnecessary portion of the Cu seed layer 3C is removed by sputter etching with the land 3A and the metal film 3B thereon as a mask. As illustrated in FIG. 13G, the interlayer dielectric film 3 is formed on the interlayer dielectric film 2. As illustrated in FIG. 13H, the interlayer dielectric film 4 having a via hole 4V is formed on the interlayer dielectric film 3 in such a manner that the metal film 3B is exposed through the via hole 4V. As illustrated in FIG. 13I, the Cu via plug 4A is formed in the via hole 4V. The land 5A and the metal film 5B, and the land 7A and the metal film 7B are formed in the same way as above. In this process, the thickness of the metal film 3B is preferably increased by the thickness of the Cu seed layer 3C in the step illustrated in FIG. 13D, in view of a decrease in thickness due to the sputter etching in the step illustrated in FIG. 13F. The step of forming the interlayer dielectric film 3 as illustrated in FIG. 13G and the step of forming the interlayer dielectric film 4 as illustrated in FIG. 13H may be successively performed. In this case, each of the interlayer dielectric films 3 and 4 is a single dielectric film.

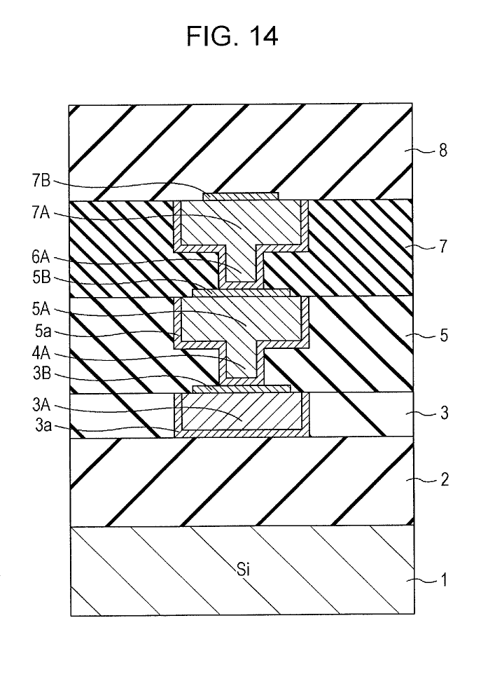

The disconnection inhibitory effect attributed to the arrangement of the metal films 3B, 5B, and 7B may be provided in an interconnection structure in which the land 5A and the Cu via plug 4A are integrally formed by a dual damascene process and in which the land 7A and the Cu via plug 6A are integrally formed by the dual damascene process, as illustrated in FIG. 14. FIG. 14 illustrates a barrier metal film 3a that covers the side walls and the bottom face of the land 3A, a barrier metal film 4a that covers the side walls and the bottom faces of the land 5A and the Cu via plug 4A, and a barrier metal film 7a that covers the side walls and the bottom faces of the land 7A and the Cu via plug 6A. Each of the barrier metal films 3a, 5a, and 7a has a thickness of, for example, 5 nm to 20 nm. In the structure illustrated in FIG. 14, the single interlayer dielectric film 5 corresponding to the interlayer dielectric films 4 and 5 illustrated in FIG. 12 is arranged. The single interlayer dielectric film 7 corresponding to the interlayer dielectric films 6 and 7 illustrated in FIG. 12 is arranged.

The structure may be formed by the process illustrated in FIG. 5A to 5G. In this case, for example, the Cu land 3A has a surface flush with a surface of the interlayer dielectric film 3. The surface of the Cu land 3A is exposed at the periphery of the metal film 3B. The same is true for the Cu lands 5A and 7A.

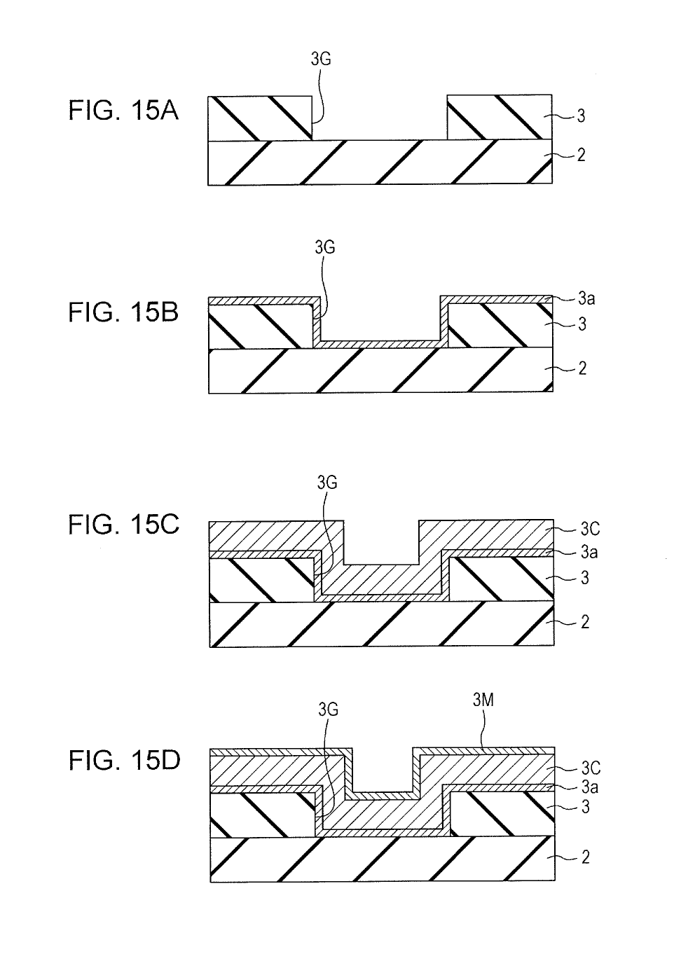

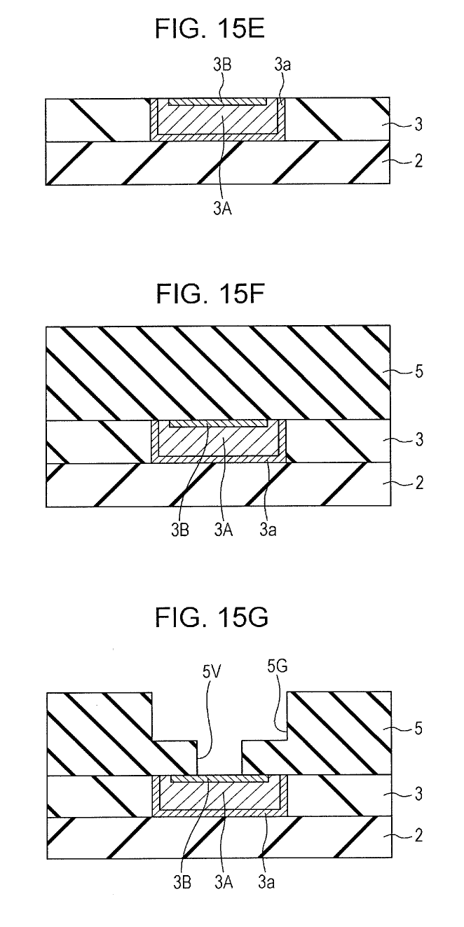

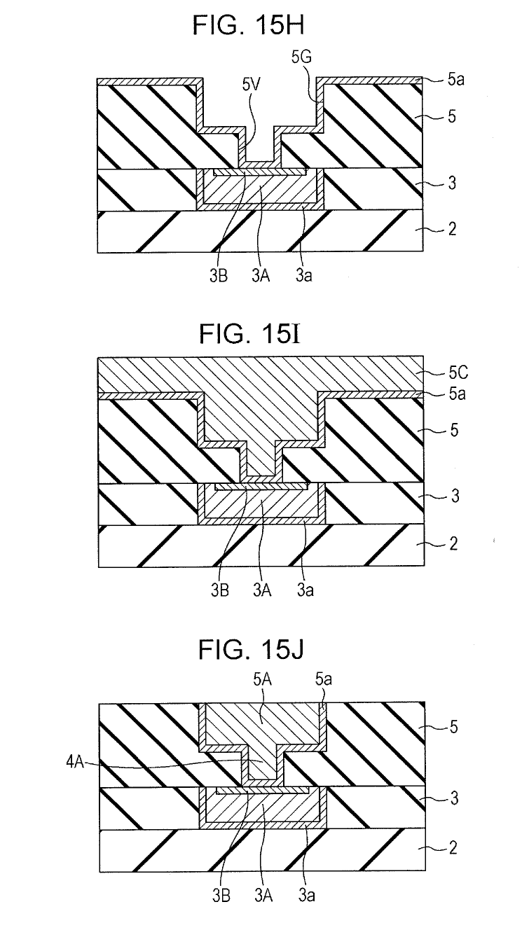

As illustrated in FIG. 15A, an interconnection trench 3G is formed in the interlayer dielectric film 3. As illustrated in FIG. 15B, the barrier metal film 3a is formed on the interlayer dielectric film 3 so as to cover the side walls and the bottom face of the interconnection trench 3G. As illustrated in FIG. 15C, a Cu layer 3C is formed by, for example, an electroplating method on the structure illustrated in FIG. 17B in such a manner that the upper surface of the Cu layer 3C in the interconnection trench 3G is substantially flush with the upper surface of the interlayer dielectric film 3. Here, the silicon substrate 1 is not illustrated.

As illustrated in FIG. 15D, a metal film 3M, corresponding to the metal film 3B, composed of Co or W is formed by, for example, a sputtering method on the Cu layer 3C and the interconnection trench 3G. The Cu layer 3C is subjected to chemical-mechanical polishing with a portion of the metal film 3M serving as a polishing stopper in the interconnection trench 3G until the upper surface of the interlayer dielectric film 3 is exposed, thereby providing a structure in which the Cu land 3A is arranged in the interconnection trench 3G and the metal film 3B is arranged on a surface of the Cu land 3A. In the structure illustrated in FIG. 15E, the surface of the Cu land 3A is exposed around the metal film 3B.

As illustrated in FIG. 15F, the interlayer dielectric film 5 is formed on the interlayer dielectric film 3. In a step illustrated in FIG. 15G, an interconnection trench 5G and a via hole 5V through which the metal film 3B is exposed are formed in the interlayer dielectric film 5. In a step illustrated in FIG. 15H, a barrier metal film 5a is formed on the interlayer dielectric film 5 so as to cover the side walls and the bottom faces of the interconnection trench 5G and the via hole 5V. In a step illustrated in FIG. 15I, a Cu layer 5C is formed in such a manner that the interconnection trench 5G and the via hole 5V are filled.

As illustrated in FIG. 15J, the Cu layer 5C is subjected to chemical-mechanical polishing until a surface of the interlayer dielectric film 5 is exposed, thereby providing a structure in which the interconnection trench 5G is filled with the Cu land 5A and in which the Cu via plug 4A extending from the Cu land 5A is in contact with the metal film 3B through the via hole 5V.

As described above, according to this embodiment, the formation of the metal films 3B, 5B, and 7B may reduce thermal stress applied to the via plugs, thereby improving the reliability of the via contact.

In this embodiment, each of the metal films 3B, 5B, and 7B preferably has a thickness of 20 to 200 nm. When each of the metal films 3B, 5B, and 7B has a thickness of less than 20 nm, the effect of inhibiting stress concentration on the via plug portions as illustrated in FIG. 11 is insufficient. When each of the metal films 3B, 5B, and 7B has a thickness exceeding 200 nm, the contact resistance with the Cu via plug 4A is increased.

In this embodiment, each of the lands 3A, 5A, and 7A preferably has a width or diameter of 10 μm to 25 μm or more.

In this embodiment, examples of a material that may be used for the metal films 3B, 5B, and 7B include Ti, Ta, Ni, and compounds mainly containing them, such as CoWP alloys, CoWB alloys, NiWP alloys, TiN, TaN, and WN, in addition to Co and W.

### Fourth Embodiment

The foregoing embodiments have been described in association with mainly circuit boards, wiring boards, and so forth. As has been described above, the embodiments are also applicable to semiconductor integrated circuit devices, such as LSIs.

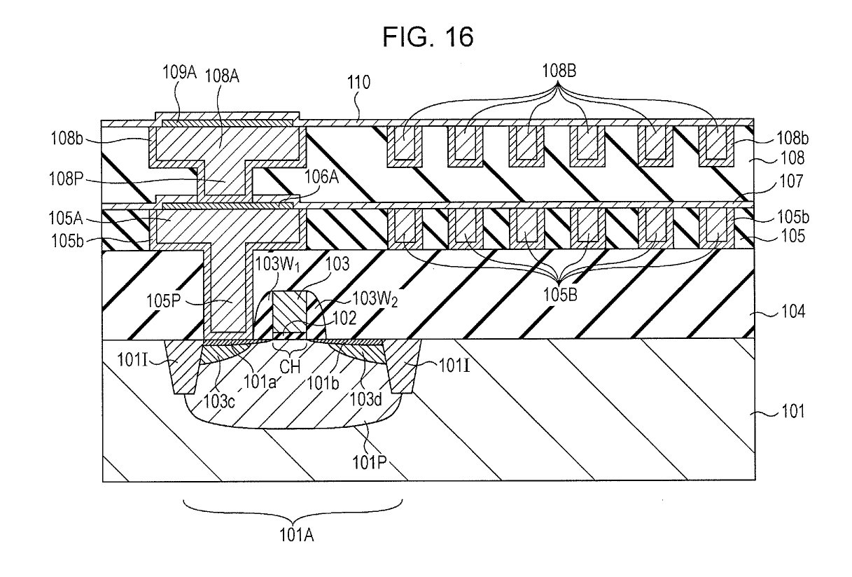

FIG. 16 is a cross-sectional view illustrating an exemplary semiconductor integrated circuit device 100.

Referring to FIG. 16, the semiconductor integrated circuit device 100 is formed on, for example, a p-type silicon substrate 101. An element region 101A is defined by shallow trench isolation (STI)-type element isolation regions 101I on the silicon substrate 101.

A p-type well 101P is formed in the element region 101A. An n+-type polysilicon gate electrode 103 is formed on the silicon substrate 101 in the element region 101A via a gate insulator 102. In response to the polysilicon gate electrode 103, a channel region CH is formed in a portion of the element region 101A directly below the polysilicon gate electrode 103. In the element region 101A, an n+-type source extension region 101a is formed on a first side of the channel region CH, and an n+-type drain extension region 101b is formed on a second side of the channel region CH.

Sidewall insulators 103W₁ and 103W₂ are formed on the first and second sides, respectively, of sidewalls of the polysilicon gate electrode 103. An n+-type source region 103c is formed in a portion of the element region 101A located on the first side of the channel region CH and outside the sidewall insulator 103W₁. An n+-type drain region 103d is formed in a portion of the element region 101A located on the second side of the channel region CH and outside the sidewall insulator 103W₂.

An insulating film 104 corresponding to the substrate 41 is formed on the silicon substrate 101 so as to cover the polysilicon gate electrode 103. An interlayer dielectric film 105 corresponding to the insulating film 42 is formed on the insulating film 104.

A wide Cu interconnection pattern 105A corresponding to the element region 101A is formed in the interlayer dielectric film 105 and is covered with a barrier metal film 105b. A via plug 105P covered with the barrier metal film 105b extends from the Cu interconnection pattern 105A through the underlying insulating film 104 and is in contact with the source region 103c. Here, the Cu interconnection pattern 105A corresponds to the first Cu layer 45A and has a depth of 100 nm and a width of 100 nm, for example. A polishing stopper film 106A composed of, for example, CoWP, NiP, Au, Ag, Ti, Ta, or W is formed on a portion of the Cu interconnection pattern 105A excluding the peripheral portion of the Cu interconnection pattern 105A.

A wiring portion in which Cu patterns 105B each having a depth of 100 nm and a width of 70 nm are arranged at a pitch of 70 nm is formed in a portion of the interlayer dielectric film 105 outside the element region 101A. The Cu patterns 105B correspond to the Cu layer 45B and are covered with the barrier metal film 105b.

The Cu interconnection pattern 105A and the Cu patterns 105B each have a planarized surface substantially flush with a surface of the interlayer dielectric film 105, excluding a portion of the Cu interconnection pattern 105A where the polishing stopper film 106A is arranged. The interlayer dielectric film 105 is covered with a SiC cap film 107.

An interlayer dielectric film 108 similar to the interlayer dielectric film 105 is formed on the SiC cap film 107. A wide Cu interconnection pattern 108A corresponding to the element region 101A is formed in the interlayer dielectric film 108 and is covered with a barrier metal film 108b. A via plug 108P covered with the barrier metal film 108b extends from the Cu interconnection pattern 108A and is in contact with the Cu interconnection pattern 105A. The Cu interconnection pattern 108A corresponds to the first Cu layer 45A and has a depth of 100 nm and a width of 100 nm, for example. A polishing stopper film 109A composed of, for example, CoWP, NiP, Au, Ag, Ti, Ta, or W is formed on a portion of the Cu interconnection pattern 108A excluding the peripheral portion of the Cu interconnection pattern 108A.

A wiring portion in which Cu patterns 108B each having a depth of 100 nm and a width of 70 nm are arranged at a pitch of 70 nm is formed in a portion of the interlayer dielectric film 108 outside the element region 101A. The Cu patterns 108B correspond to the Cu layer 45B and are covered with the barrier metal film 108b.

The Cu interconnection pattern 108A and the Cu patterns 108B each have a planarized surface substantially flush with a surface of the interlayer dielectric film 108, excluding a portion of the Cu interconnection pattern 108A where the polishing stopper film 109A is arranged. The interlayer dielectric film 108 is covered with a SiC cap film 110.

Also in this structure, the formation of the Cu interconnection pattern 105A or the Cu interconnection pattern 108A by electroplating is performed separately from the formation of the Cu patterns 105B or the Cu patterns 108B by electroplating. This inhibits the occurrence of dishing in the wide Cu interconnection pattern 105A or 108A while the occurrence of underplating immediately after the deposition of the Cu layer and an excessive deposition of the Cu layer in the field portion are inhibited, as described in Table 1 illustrated in FIG. 17, Table 2 illustrated in FIG. 18, and FIGS. 9A and 9B. For example, in the case where the upper via plug 108P is in contact with the wide, lower Cu interconnection pattern 105A as illustrated in FIGS. 13A to 13I, a problem in which an end of the via plug 108P does not reach a surface of the Cu interconnection pattern 105A is solved. Thereby, the multilayer interconnection structure having reliable contact may be provided.

Also in this embodiment, the arrangement of the polishing stopper films 106A and 109A inhibits stress concentration on the Cu via plugs 108P and 105P and inhibits void concentration, thereby providing highly reliable contact.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a first insulating film;
an interconnection trench on a surface of the first insulating film;
an interconnection pattern composed of Cu, the interconnection trench being filled with the interconnection pattern;
a metal film on a surface of the interconnection pattern, the metal film having a higher elastic modulus than Cu;
a second insulating film on the first insulating film; and
a via plug composed of Cu and arranged in the second insulating film, the via plug being in contact with the metal film.

2. The electronic device according to claim 1,
wherein the interconnection pattern has a surface flush with the surface of the first insulating film, and the surface of the interconnection pattern is exposed around the metal film.

3. The electronic device according to claim 1,
wherein the metal film has a surface flush with the surface of the first insulating film.

4. The electronic device according to claim 1,
wherein the metal film is composed of at least one metal element selected from the group consisting of Co, W, Ti, Ta, and Ni, or
wherein the metal film is composed of a compound mainly containing the metal element.

5. The electronic device according to claim 1,
wherein the metal film has a thickness of 20 nm to 200 nm.

6. A method for producing an electronic device, comprising:
forming an interconnection trench in a first insulating film;
forming a Cu layer on the first insulating film, the interconnection trench being filled with the Cu layer;
depositing a metal film on the Cu layer, the metal film having a higher elastic modulus than Cu;
subjecting the Cu layer to chemical-mechanical polishing with the metal film serving as a stopper;
forming a second insulating film on the first insulating film so as to cover the metal film; and
forming a Cu via plug in the second insulating film so as to be in contact with the metal film.

7. The method according to claim 6,
wherein the forming the Cu layer is performed in such a manner that a surface of the Cu layer in the interconnection trench is substantially flush with a surface of the first insulating film.

8. A method for producing an electronic device, comprising:
forming a resist film on a first insulating film, the resist film having a resist opening portion;
forming a Cu interconnection pattern in the resist opening portion by a plating method with the resist film serving as a mask;
forming a metal film on the resist film so as to cover the Cu interconnection pattern, the metal film having a higher elastic modulus than Cu;
removing the resist film together with a portion of the metal film located on the resist film by a lift-off process;
forming a second insulating film on the first insulating film so as to cover the Cu interconnection pattern and the metal film; and
forming a Cu via plug in the second insulating film so as to be in contact with the metal film.

9. The method according to claim 8,
wherein the forming the Cu interconnection pattern by the plating method is performed with a Cu film formed on the first insulating film, the Cu film serving as a seed layer, and
wherein after the lift-off process, the method further comprises removing the seed layer from a surface of the first insulating film with the Cu interconnection pattern and the metal film serving as a mask.

10. The method according to claim 6,
wherein the metal film is composed of at least one metal element selected from the group consisting of Co, W, Ti, Ta, and Ni, or
wherein the metal film is composed of a compound mainly containing the metal element.
